(19) United States
(12) Patent Application Publication
(10) Pub. No.: US 2026/0129964 A1
(43) Pub. Date: May 7, 2026

(54) SEMICONDUCTOR DEVICE WITH BACKSIDE ISOLATION RING FOR LATCH-UP IMMUNITY

(71) Applicant: INTERNATIONAL BUSINESS MACHINES CORPORATION, ARMONK, NY (US)

(72) Inventors: Masoud Zabihi, Schenectady, NY (US); Ruilong Xie, Niskayuna, NY (US); Robert Gauthier, Williston, VT (US); Anindya Nath, Watervliet, NY (US); Anthony I-Chih Chou, Guilderland, NY (US)

(21) Appl. No.: 18/939,454

(22) Filed: Nov. 6, 2024

(51) Int. Cl. H01L 27/092; H01L 21/762; H01L 21/8234; H01L 23/528; H01L 27/02; H01L 29/08

(52) U.S. Cl. CPC H10D 84/854; H10D 62/151; H10D 84/013; H10D 84/0149; H10D 84/038; H10D 89/713; H10W 10/014; H10W 10/17; H10W 20/427

(57) ABSTRACT

A semiconductor device includes a passive device including a first backside contact on a first side of the passive device, a second backside contract on a second side of the passive device, a spacer liner over sidewalls of the first backside contact and the second backside contact, and a shallow trench isolation (STI) above the first backside contact and the second backside contact and partially covering a top surface of the first backside contact and the second backside contact. The spacer liner is configured to prevent carrier transportation from the passive device.

### BACKGROUND

### Technical Field

The present disclosure generally relates to semiconductors, and more particularly, to semiconductors with backside isolation ring for latch-up immunity structure, and methods of creation thereof.

### Description of Related Art

The continuous miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. Various functionalities, including processing and storage, are increasingly being integrated within a single chip, enabling more compact and efficient systems.

### SUMMARY

According to an embodiment, a semiconductor device includes a passive device including a first backside contact on a first side of the passive device, a second backside contract on a second side of the passive device, a spacer liner over sidewalls of the first backside contact and the second backside contact, a shallow trench isolation (STI) above the first backside contact and the second backside contact and partially covering a top surface of the first backside contact and the second backside contact. The spacer liner is configured to prevent carrier transportation from the passive device.

In one embodiment, the passive device further includes a bottom dielectric layer (BILD) between the first backside contact and the second backside contact, a well region between the STI and the BILD, and a metal interconnect connecting the passive device to a backside power delivery network (BSPDN).

In one embodiment, the semiconductor device includes a set of P-type doped regions and a set of N-type doped regions over the STI and the doped region, and a first set of gate regions.

In one embodiment, the spacer liner is made of a high-k dielectric material.

In one embodiment, the passive device is electrically connected to a back end of line (BEOL) through a via and a first contact.

In one embodiment, the semiconductor device includes an active device having source/drain regions, a second set of gate regions, and a second contact.

In one embodiment, the active device is electrically connected to a back end of line (BEOL) through a second via.

In one embodiment, the active device further comprises alternative layers extended horizontally between two adjacent source/drain regions.

In one embodiment, the alternative layers include silicon.

According to an embodiment, a method of fabricating a semiconductor device includes forming a passive device including forming a first backside contact, forming a second backside contact, forming a spacer liner over sidewalls of the first backside contact and the second backside contact, and forming a shallow trench isolation (STI) above the first backside contact and the second backside contact and partially covering a top surface of the first backside contact and the second backside contact, wherein the spacer liner is configured to prevent carrier transportation from the passive device.

In one embodiment, the method includes forming a bottom dielectric layer (BULD) adjacent to the first backside contact and the second backside contact, forming a well region between the STI and the BILD, and forming a metal interconnect connecting the passive device to a backside power delivery network (BSPDN).

In one embodiment, the method includes forming a set of P-type doped regions and a set of N-type doped regions over the STI and the doped region, and forming a first set of gate regions.

In one embodiment, the method includes establishing an electrical connection between the passive device and a back end of line (BEOL) through a first via and a first contact.

In one embodiment, the method includes forming an active device, including forming source/drain regions, forming a second set of gate regions between the source/drain regions, and forming a second contact over each of the source/drain regions.

In one embodiment, the method includes forming alternative layers extended horizontally between two adjacent source/drain regions.

In one embodiment, the method includes establishing an electrical connection between the active device and a back end of line (BEOL) through a second via.

According to an embodiment, a semiconductor device includes a passive device, having a first backside contact on a first side of the passive device, a second backside contract on a second side of the passive device, a first interconnect connecting the first backside contact to a backside power delivery network (BSPDN) on a backside of the passive device, a second interconnect connecting the second backside contact to the BSPDN, and a spacer liner over sidewalls of the first backside contact and the second backside contact. The spacer liner is configured to prevent carrier transportation from the passive device.

In one embodiment, the semiconductor device includes a shallow trench isolation (STI) above the first backside contact and the second backside contact and covering a top surface of the first backside contact and the second backside contact.

In one embodiment, the semiconductor device includes a bottom dielectric layer (BILD) between the first interconnect and the second interconnect, a first well region between the first backside contact and the second backside contact, and a second well region between the STI and the first well region.

In one embodiment, the semiconductor device includes an active device having source/drain regions, gate regions; and a contact.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1D illustrate the latch-up formation, the undershoot and overshoot scenarios in a conventional semiconductor device.

FIGS. 1E-1F illustrate a sideview of a latch-up prone region in a conventional semiconductor device.

FIGS. 2A-2B illustrate a semiconductor device, in accordance with some embodiments.

FIGS. 3A-3B illustrate a semiconductor device after the formation of the front end of line, middle end of line, and back end of line, in accordance with some embodiments.

FIGS. 4A-4B illustrate a semiconductor device after wafer flip and substrate removal, in accordance with some embodiments.

FIGS. 5A-5B illustrate a semiconductor device after patterning of the backside of the semiconductor device, in accordance with some embodiments.

FIGS. 6A-6B illustrate a semiconductor device after the formation of the spacer layer, in accordance with some embodiments.

FIGS. 7A-7B illustrate a semiconductor device after the formation of mask, in accordance with some embodiments.

FIGS. 8A-8B illustrate a semiconductor device after the removal of the mask, in accordance with some embodiments.

FIGS. 9A-9B illustrate a semiconductor device after the formation of the backside interlayer dielectric, in accordance with some embodiments.

FIGS. 10A-10B illustrate a semiconductor device after the backside contact patterning in accordance with some embodiments.

FIGS. 11A-11B illustrate a semiconductor device after the removal of the etch stop layer, in accordance with some embodiments.

FIGS. 12A-12B illustrate a semiconductor device after the metallization of the backside contact, in accordance with some embodiments.

FIGS. 13A-13B illustrate a semiconductor device after the formation of the backside interconnect, in accordance with some embodiments.

FIGS. 14A-14B illustrate a semiconductor device after the formation of the front end of line, middle end of line, and back end of line, in accordance with some embodiments.

FIGS. 15A-15B illustrate a semiconductor device after wafer flip and substrate removal, in accordance with some embodiments.

FIGS. 16A-16B illustrate a semiconductor device after patterning of the backside of the semiconductor device, in accordance with some embodiments.

FIGS. 17A-17B illustrate a semiconductor device after the formation of the spacer layer, in accordance with some embodiments.

FIGS. 18A-18B illustrate a semiconductor device after the formation of mask, in accordance with some embodiments.

FIGS. 19A-19B illustrate a semiconductor device after the removal of the mask, in accordance with some embodiments.

FIGS. 20A-20B illustrate a semiconductor device after the formation of the backside interlayer dielectric, in accordance with some embodiments.

FIGS. 21A-21B illustrate a semiconductor device after the backside contact patterning in accordance with some embodiments.

FIGS. 22A-22B illustrate a semiconductor device after the removal of the etch stop layer, in accordance with some embodiments.

FIGS. 23A-23B illustrate a semiconductor device after the metallization of the backside contact, in accordance with some embodiments.

FIGS. 24A-24B illustrate a semiconductor device after the formation of the backside interconnect, in accordance with some embodiments.

FIG. 25 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

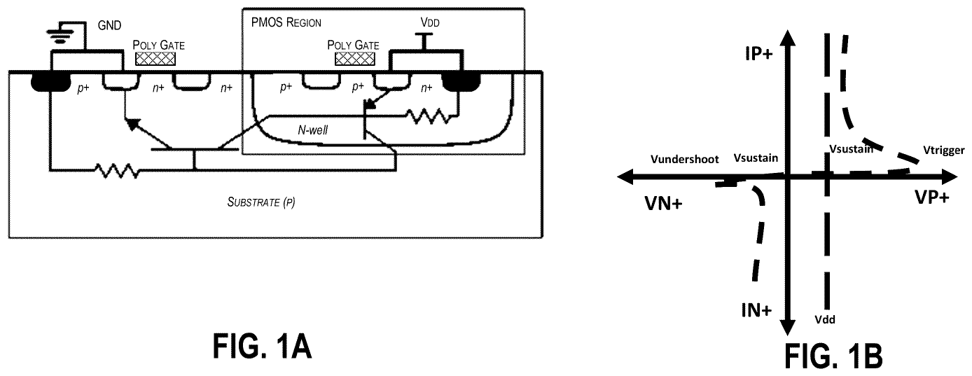

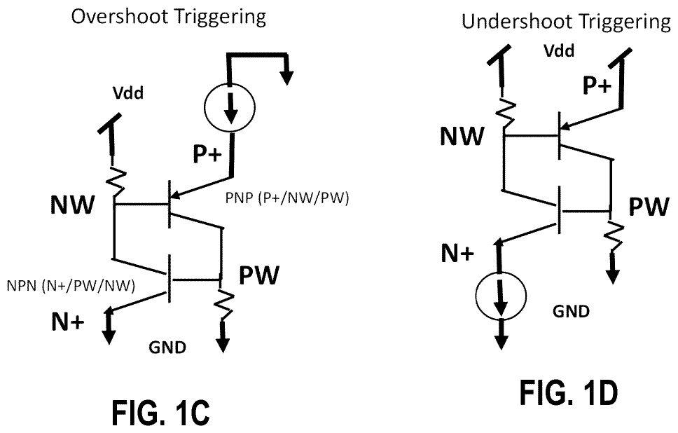

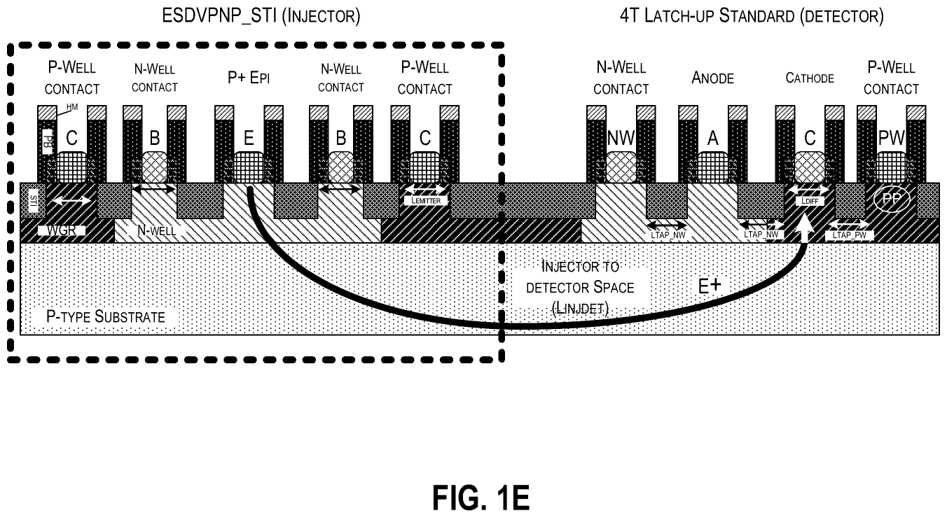

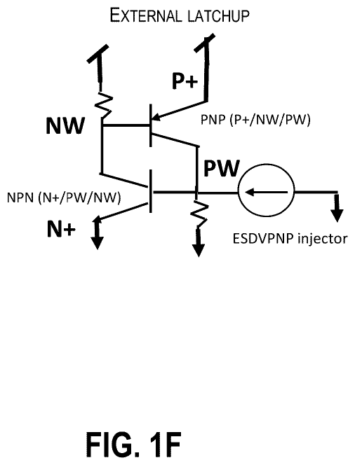

Backside interconnect is recognized as the industry go-to direction for advancing semiconductor technology. By routing interconnections on the backside of the semiconductor wafer, this approach effectively increases the available area for active device components on the frontside, thereby enhancing overall device performance and density. The implementation of backside interconnects allows for more efficient power distribution and signal routing, reducing resistance and inductance associated with longer interconnect paths. Preventing latch-up in integrated circuits is desired due to its potential to cause catastrophic failure. Latch-up refers to the inadvertent creation of a low-impedance path between the power supply rails, typically triggered by certain electrical conditions such as overshoot, undershoot, or transient currents. This low-impedance path can lead to excessive current flow, causing overheating, circuit malfunction, or permanent damage to the integrated circuit. Effective latch-up prevention strategies require careful layout design, proper isolation techniques, and the incorporation of guard rings or substrate ties to mitigate the risk of latch-up occurrences. FIGS. 1A-1D illustrate two possible scenarios, e.g., overshoot and undershoot, for occurrence of the parasitic positive-negative-positive-negative (PNPN) silicon-controlled rectifier (SCR) in a conventional complementary metal-oxide semiconductor (CMOS).

In semiconductor devices, overshoot and undershoot are phenomena that can adversely affect signal integrity. Overshot occurs when the voltage of a signal exceeds its intended threshold (e.g., maximum) value during a transition, often due to the inductive and capacitive properties of the interconnects. This excessive voltage can lead to signal distortion, potential damage to the device, and increased electromagnetic interference (EMI). Similarly, undershoot refers to the scenario where the signal voltage drops below its intended threshold (e.g., minimum) value, which can also cause signal integrity issues, increased susceptibility to noise, and potential triggering of unintended states in digital circuits. Both overshoot and undershoot need to be considered in high-speed and high-frequency circuit design, necessitating the use of proper termination techniques, controlled impedance routing, and careful signal integrity analysis to reduce (e.g., minimize) their impact.

The parasitic PNPN SCR structure in complementary metal-oxide-semiconductor (CMOS) technology is a factor in latch-up phenomena. The parasitic SCR is formed inadvertently during the fabrication of CMOS devices, including a PNP transistor and an NPN transistor that are interconnected in such a way that they can form a positive feedback loop. When certain conditions, such as high current injection or excessive voltage, are met, this feedback loop can become self-sustaining, leading to a latch-up condition. Once triggered, the parasitic SCR can conduct a significant amount of current, resulting in elevated temperatures, potential destruction of the device, and failure of the integrated circuit. FIGS. 1E-IF illustrate the formation of the parasitic PNPN SCR which causes the latch-up. The latch-up can occur between a first N-well region below the P-type doped regions and the N-type doped regions and a second N-well region and via the STI and a P-well region.

In current semiconductor technology, electrostatic discharge (ESD) protection devices often utilize front-side guard rings to mitigate latch-up risks. A guard ring is a region of doped semiconductor material that surrounds sensitive components within an integrated circuit. Its purpose is to collect and redirect charge carriers—such as electrons or holes—that may be injected during ESD events or from neighboring devices. By capturing these carriers, the guard ring aims to prevent them from triggering parasitic structures that can lead to latch-up.

However, this approach presents several drawbacks and limitations. The inclusion of front-side guard rings consumes additional area on the chip, which is a significant concern in modern integrated circuits where space is at a premium. As device dimensions shrink and integration density increases, the area occupied by guard rings becomes more problematic, limiting the potential for further miniaturization and adding to manufacturing costs. Moreover, despite the presence of guard rings, carriers can still be injected into adjacent devices. These injected carriers may bypass the guard ring and activate parasitic SCRs in neighboring components, invoking latch-up and potentially causing device failure.

Latch-up is a particularly severe issue because it creates a low-resistance path between the power supply and ground, leading to excessive current flow. This can result in malfunction, overheating, and permanent damage to the integrated circuit. The limitations of front-side guard rings in effectively preventing latch-up highlight the need for alternative solutions that can provide robust protection without compromising device size or performance.

The present disclosure addresses these challenges by introducing a semiconductor device that incorporates a backside isolation ring for latch-up immunity in a backside power delivery network (BSPDN). Instead of relying on front-side guard rings, the disclosed method implements an isolation ring on the backside of the semiconductor wafer. By doing so, it effectively isolates adjacent ESD devices from one another, eliminating the risk of latch-up caused by carrier injection into neighboring devices.

The backside isolation ring serves as a barrier that prevents carriers generated during ESD events or normal operation from reaching and affecting nearby components. By isolating the devices from the backside, the method overcomes the limitations of front-side guard rings, which can be bypassed by carriers traveling through the substrate or along unintended paths. The backside isolation ring provides a more comprehensive and reliable means of preventing latch-up, enhancing the overall robustness of the integrated circuit.

An additional advantage of this approach is the reduction in the area required for ESD protection devices. The disclosed method eliminates the need for the collector area associated with the parasitic SCR that contributes to latch-up. By removing or minimizing the collector area, the ESD device becomes more compact, freeing up valuable chip space for additional functionality or further scaling down of device dimensions. This reduction in area does not compromise the effectiveness of the ESD protection but rather enhances it by eliminating a key component involved in latch-up.

Incorporating backside isolation rings is particularly important in backside power delivery network (BSPDN) technology because it addresses the unique challenges associated with backside power delivery. Traditional front-side isolation methods are less effective in this context, as the backside power delivery can introduce new pathways for carriers that may lead to latch-up. The backside isolation ring effectively blocks these pathways, ensuring that the devices remain immune to latch-up even when the power is supplied from the backside.

By providing a robust solution to latch-up without increasing the chip area or compromising device performance, the present disclosure supports the advancement of semiconductor technology. The disclosed semiconductor device enables higher integration densities and improved reliability, which are critical for meeting the demands of modern electronic devices that require more functionality in smaller form factors. The disclosed semiconductor device's compatibility with BSPDN and BPR technologies positions it as a valuable option for future developments in semiconductor fabrication, contributing to more efficient and reliable integrated circuits.

Accordingly, the teachings herein provide methods and systems of semiconductor device formation with the backside isolation ring for latch up immunity. The techniques described herein may be implemented in a number of ways. Example implementations are provided below with reference to the following figures.

Example Semiconductor Device with Backside Isolation Ring for Latch Up Immunity Structure

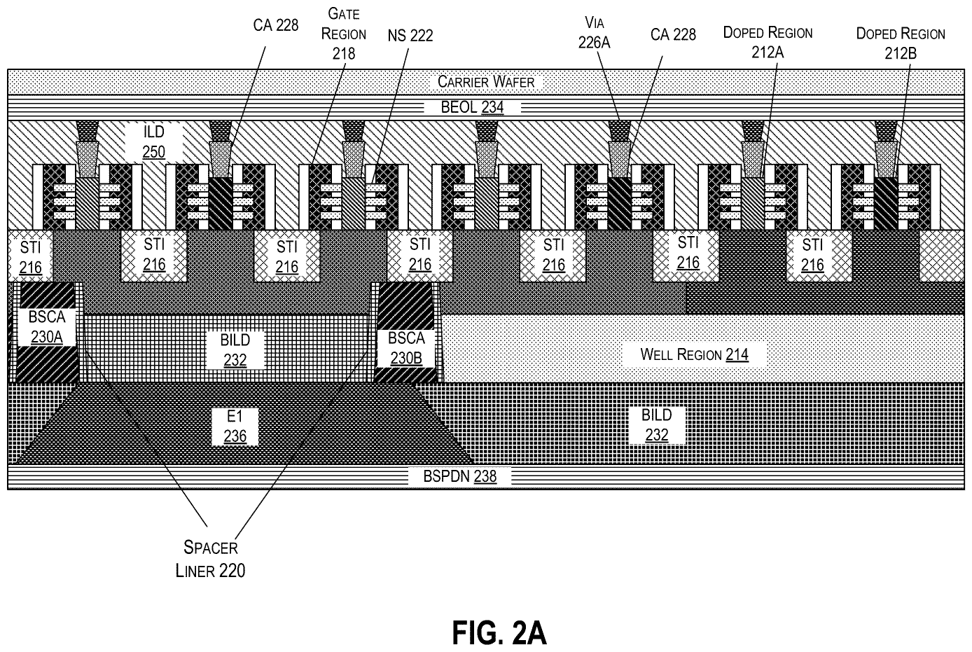

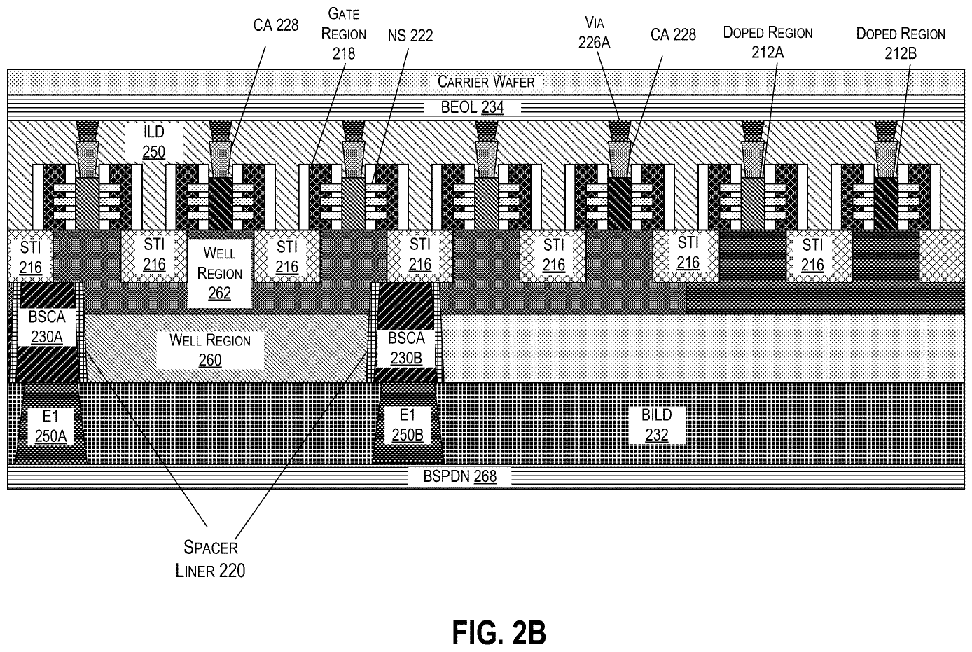

Reference now is made to FIGS. 2A-2B, which are simplified cross-section view of a semiconductor device, consistent with an illustrative embodiment.

The semiconductor device integrates both a passive electrostatic discharge (ESD) protection section and an active operational section. The passive section, which serves as the ESD protection, includes a first backside contact, BSCA 230A, on one side and a second backside contact, BSCA 230B, on the opposite side. The BSCA 230A and BSCA 230B establish electrical connections from the backside of the semiconductor device, enhancing current flow and signal transmission efficiency. Covering the sidewalls of both backside contacts, BSCA 230A and BSCA 230B, is a spacer liner 220 made of a high-k dielectric material. The spacer liner 220 acts as an insulating barrier, preventing unwanted carrier transportation from the passive section. By inhibiting the movement of charge carriers, the spacer liner 220 enhances the device's reliability and reduces (e.g., minimizes) leakage currents. High-k dielectrics possess superior insulating properties and allow greater capacitance without increasing leakage. The semiconductor device can further include frontside contacts, CA 228.

Above the BSCA 230A and BSCA 230B lies a shallow trench isolation structure, STI 216, which partially covers the top surfaces of the BSCA 230A and BSCA 230B. The STI 216 provides electrical isolation between different regions within the semiconductor device, preventing electrical crosstalk and maintaining signal integrity.

The STI 216 can electrically isolate different components by filling the trenches with an insulating material, such as silicon dioxide. The STI 216 can prevent electrical interference and crosstalk between adjacent devices, ensuring that each component operates independently without affecting its neighbors. The STI 216, which can be composed of silicon dioxide, acts as the dielectric material separating the various components.

Between the STI 216 and a bottom interlayer dielectric layer, BILD 232, there is a well region 214. The well region 214 can be doped to alter its electrical properties, allowing for customization of the device's performance characteristics.

The BILD 232 is situated between the BSCA 230A and BSCA 230B, serving as an additional insulating layer that enhances electrical isolation within the device. The BILD 232 helps prevent unintended interactions between different conductive regions, thereby improving overall device performance. Connecting the passive section to a backside power delivery network, BSPDN 238, is a metal interconnect 236. The metal interconnect 236 facilitates distributing power throughout the device, ensuring that the ESD protection mechanism functions effectively when needed.

In the active section of the semiconductor device, there are source and drain regions which are fundamental to transistor operation. In some embodiments, alternative layers, e.g., nanosheet gates, NS 222, can extend horizontally between adjacent source and drain regions, which may include silicon due to its excellent semiconducting properties essential for controlling the flow of electrical current within the device.

Over the STI 216 and the well region 214, there are sets of p-type and n-type doped regions, doped region 212A and doped region 212B. The doped region 212A and doped region 212B can form p-n junctions. Above the doped region 212A and doped region 212B, a first set of gate regions 218 is established. The first set of gate regions 218 control the electrical conductivity between the doped regions, thereby regulating the device's switching and amplification capabilities.

Each pair of the doped region 212B and the doped region 212A can be created by doping two regions, one with a type P dopant, which introduces an excess of positive charge carriers (holes), and the other with a type N dopant, which introduces an excess of negative charge carriers (electrons). An N-well region and a P-well region can form the p-n junction of the semiconductor device. The p-n junction can control the flow of electrical current within the semiconductor device. The p-n junction can be created by doping two adjacent regions, one with a type P dopant, which introduces an excess of positive charge carriers (holes), and the other with a type N dopant, which introduces an excess of negative charge carriers (electrons). At the interface between the P and N regions, a depletion region forms due to the diffusion of electrons from the N region into the P region and the diffusion of holes in the opposite direction. Such a diffusion process continues until the electric field created by the accumulation of charge at the junction balances the diffusion forces, resulting in a zone depleted of free charge carriers. In its natural state, the p-n junction allows current to flow more easily in one direction than in the opposite.

When forward biased, i.e., positive voltage applied to the P side relative to the N side, the depletion region narrows, lowering the barrier for charge carriers to move across the junction, and allowing current to flow through the device. Conversely, when reverse-biased, i.e., negative voltage applied to the P side, the depletion region widens, increasing the barrier for charge movement, and significantly reducing the flow of current.

The CA 228, located over doped regions 212A, the doped region 212B and the source/drain regions, can establish connections between the semiconductor device and the BEOL 234 through the first via 226A and the second via. The CA 228 can ensure efficient electrical routing and connectivity within the semiconductor device. The fabrication of the CA 228 can involve lithography and etching processes to define the contact area. The CA 228 can be made using conductive materials such as copper (Cu) or tungsten (W).

The semiconductor device can include several structural and functional elements that contribute to its performance and integration within semiconductor technology. The semiconductor device can further include an interlayer dielectric (ILD) situated above the STI 216. The ILD 250 can serve as an insulating layer that separates various conducting layers and components within the semiconductor device. The ILD 250 can be a layer of insulating material to electrically isolate and provide mechanical support between different layers of conducting and active components. The ILD 250 can enable efficient signal transmission, reduce crosstalk, and ensure the proper functioning of the semiconductor device. In an embodiment, the ILD 250 can electrically isolate adjacent conducting layers or active components in the semiconductor device. By providing insulation between different layers, the ILD 250 can prevent electrical shorts, reduce (e.g., minimize) leakage current, and ensure that signals are directed only along the desired pathways. In some embodiments, the ILD 250 can help reduce parasitic capacitance between adjacent metal interconnects or active devices and provide mechanical support to the passive device's structure.

In several embodiments, the BILD 232 can provide structural support to the semiconductor device by maintaining the mechanical integrity and stability of the semiconductor device. The BILD 232 can further help prevent the warping, bending, or cracking of the substrate, particularly during the manufacturing process or subsequent handling. The BILD 232 can ensure that the semiconductor device remains mechanically robust and maintains its dimensional stability.

In an embodiment, the BILD 232 can also serve as a planarization layer in the semiconductor device fabrication process. As various layers are deposited and patterned on the front side of the semiconductor device, irregularities or topographic variations may arise. The BILD 232 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 232 can contribute to improved overall passive device performance. In several embodiments, BILD 232 can facilitate wafer-level testing of the semiconductor device. By providing electrical isolation between the active regions and the backside contact, individual passive device or elements on the semiconductor device can be electrically accessed and tested without interference from neighboring devices or components. This enables efficient and accurate wafer-level testing, ensuring quality control during semiconductor manufacturing.

The semiconductor device is designed to be area-efficient by eliminating the need for a guard ring around the ESD section. Traditionally, guard rings are used to isolate the ESD device from other components on the chip, preventing interference and providing a dedicated path for discharge currents. However, the guard rings can occupy a significant portion of the chip area-up to 20% of the ESD device's area-which is substantial in the context of integrated circuits where space is at a premium. By removing the guard ring, the implementation area of the ESD device is significantly decreased. Such a reduction in area allows for more components to be integrated onto the semiconductor chip or for the overall size of the chip to be reduced. The space saved can be utilized to add more functionality or to make the device more suitable for applications where size constraints are critical, such as in mobile devices or wearable technology.

Additionally, the design of the semiconductor device offers advantages similar to those of a silicon-on-insulator (SOI) structure. In an SOI structure, a thin layer of insulating material separates the active silicon layer from the bulk substrate. The configuration reduces parasitic capacitance between the device and the substrate, which is known as substrate coupling capacitance. High substrate coupling capacitance can lead to unwanted signal coupling, noise, and power losses, adversely affecting the performance of high-speed and high-frequency circuits. By resembling an SOI structure, the semiconductor device reduces (e.g., minimizes) substrate coupling capacitance without the need for the complex fabrication processes associated with true SOI technology. This reduction in capacitance enhances the electrical performance of the device by decreasing signal delay and power consumption. It also improves signal integrity, as there is less interference from the substrate, which is particularly beneficial in mixed-signal applications where digital and analog circuits coexist on the same chip.

The combination of area efficiency and improved (e.g., minimized) substrate coupling capacitance means that the semiconductor device not only occupies less space but also operates more effectively, as It delivers higher performance while reducing manufacturing costs associated with larger chip areas and complex isolation techniques. This makes the device highly advantageous for modern electronic applications that demand compact size, high speed, and efficient power usage.

FIG. 2B illustrates a semiconductor device, in accordance with some embodiments. In some embodiments, the semiconductor device incorporates a passive component designed with several integral features to enhance its performance and efficiency. The passive section includes a first backside contact, BSCA 230A, positioned on one side and a second backside contact, BSCA 230B, located on the opposite side. Connecting the BSCA 230A to a BSPDN 268 on the backside of the passive device is an interconnect 250A. Similarly, a second interconnect 250B connects the BSCA 230B to the BSPDN 268. The BSPDN 268 serves as a network for distributing power efficiently across the backside of the semiconductor device. By utilizing backside contacts and interconnects, the device can achieve better power distribution and reduce (e.g., minimize) voltage drops, which is particularly beneficial in high-density integrated circuits where power integrity is critical.

Located between the BSCA 230A and BSCA 230B is a first well region 260. The first well region 260 can be doped with specific impurities to modify its electrical properties, allowing precise control over conductivity and enabling the customization of the semiconductor material's behavior in this area. Above the first well region 260, and between it and the STI 216, is a second well region 262. The second well region 262 provides additional control over the device's electrical characteristics, enabling fine-tuning of parameters such as threshold voltage, drive current, and switching speed.

Example Act of Fabrication of Semiconductor Device with Backside Isolation Ring for Latch Up Immunity Structure

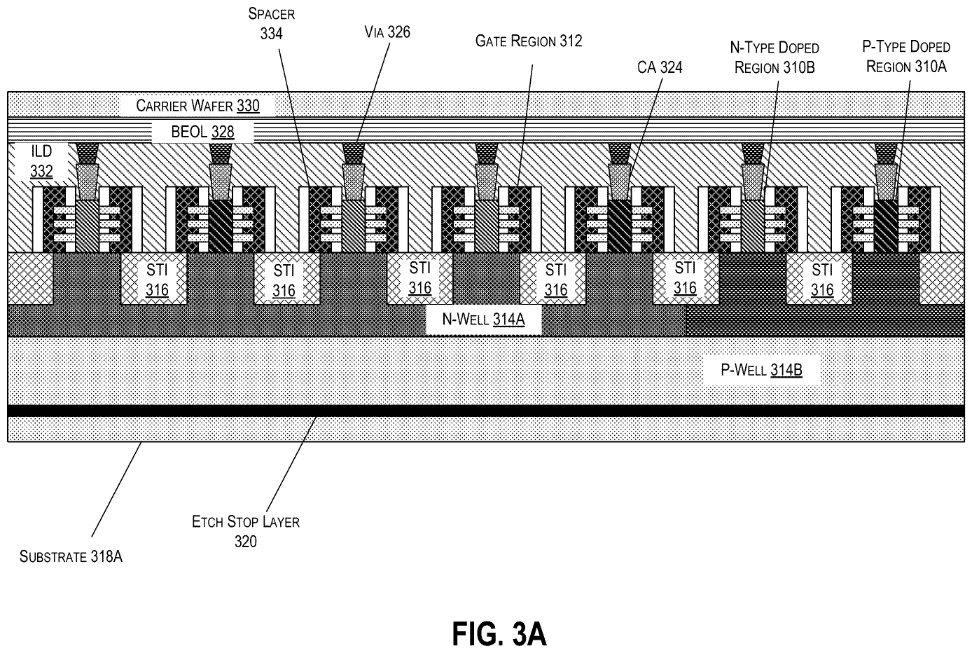

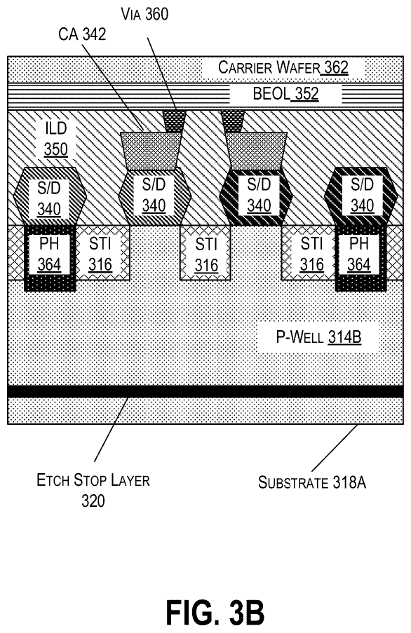

With the foregoing description of an example semiconductor device, it may be helpful to discuss an example process of manufacturing the same. To that end, FIGS. 3-13 illustrate various acts in the manufacture of a semiconductor device, consistent with illustrative embodiments.

Reference now is made to FIGS. 3A-3B, which are simplified cross-section views of a semiconductor device, after the front end of line (FEOL), middle of line (MOL), and BEOL, consistent with an illustrative embodiment. As noted above, the semiconductor device includes a latch-up prone region (which can be in parts of the passive device in the vicinity of the active device) and an active device. Figures denoted by A show the latch-up prone regions and figures denoted by B depict the active device region of the semiconductor device.

The latch-up prone region can a set of P-type doped regions 310A, a set of N-type doped regions 310B, gate regions 312, an N-well region 314A, a P-well region 314B, a first shallow trench isolation, STI 316, a first substrate 318A, an etch stop layer 320, frontside contacts, CA 324, a first set of vias 326, a back end of line, BEOL 328, a carrier wafer 330, an interlayer dielectric, ILD 332, and spacers 334.

The active device, which can be a FET, includes source/drain regions, S/D 340, frontside contacts, CA 342, ILD 350, BEOL 352, a STI 316, a second set of vias 360, a carrier wafer 362, PH 364, the first substrate 318A, and the etch stop layer 320. It should be noted that, in various embodiments, the latch-up prone region and the active device can share one or more of the BEOL, carrier wafer, first substrate, second substrate, etch stop layer, ILD and STI can be common.

In the illustrative example depicted in FIGS. 3A-3B, the semiconductor device is depicted as being on silicon as the first substrate 318A, while it will be understood that other types as the first substrate 318A may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 318A can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 320 is formed over the first substrate 318A. The etch stop layer 320 can be a thin layer of material incorporated into the structure of the semiconductor device to provide a selective barrier against etching processes, preventing further removal of underlying materials during fabrication. The etch stop layer 320 can enable precise control over the etching depth and help define the desired device dimensions. The etch stop layer 320 can further provide a stopping point for the etching process, ensuring that specific layers or regions are not etched beyond a certain point, leading to accurate patterning and control of critical features. The etch stop layer 320 can create a distinct separation between different layers or components within the device structure, and prevent the undesired etching of underlying layers or materials, enabling the creation of complex, multi-layered structures with well-defined interfaces and boundaries. In some embodiments, the etch stop layer 320 acts as a protective barrier for sensitive or delicate materials to shield such materials from aggressive etchants, preventing damage or degradation during subsequent fabrication steps.

In some embodiments, prior to forming the etch stop layer 320, the first substrate 318A is prepared by cleaning and removing any impurities or oxide layers. The etch stop layer 320 is deposited onto the first substrate 318A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 320 can then be selectively etched, stopping at a predetermined depth, while protecting the underlying layers. After the etching process, the remaining photoresist can be removed through stripping techniques. While in some embodiments, SiGe is used to form the etch stop layer 320, in some embodiments, silicon nitride (SiN), silicon oxide (SiO2), or silicon oxynitride (SiON) can be used as the etch stop layer 320.

The spacers 334 can be thin insulating layers or materials placed on the sidewalls of the gate regions 312. The spacers 334 can help control the effective channel length of the latch-up prone region. In an embodiment, the spacers 334 can allow for control over the channel's conductive properties, including resistance and carrier mobility, which can contribute to improved performance of the semiconductor device. The spacers 334 can be a low-k material.

In some embodiments, the spacers 334 can act as insulating layers between the gate regions 312 and the set of N-type doped regions 310B and the set of P-type doped regions 310A. That is, the spacers 334 can help prevent current leakage or short circuits between the gate regions 312 and the set of N-type doped regions 310B and the set of P-type doped regions 310A. Such isolation can help maintain the integrity of the passive device's electrical operation and prevent unintended current flow that could negatively impact the performance of the semiconductor device and reliability.

In further embodiments, the spacers 334 can be utilized to modulate the overlapping capacitance between the gate regions 312 and the set of N-type doped regions 310B and the set of P-type doped regions 310A. Overlapping capacitance can affect the passive device's electrical characteristics, such as threshold voltage and switching behavior. Thus, by adjusting the thickness and material properties of the spacers 334 the overlapping capacitance can be optimized, which can allow for better control and modulation of the passive device's behavior. In several embodiments, the spacers 334 can help mitigate the short-channel effects by physically separating the gate regions 312 from the set of N-type doped regions 310B and the set of P-type doped regions 310A. To that end, the spacers 334 can create a barrier that restricts the extension of the electric field into the channel region. This mitigation can improve the device's performance, reduce power consumption, and enhance overall device reliability.

In an embodiment, the spacers 334 can serve as barriers that prevent the lateral diffusion of dopant atoms from the set of N-type doped regions 310B and the set of P-type doped regions 310A, and into the channel region during the doping process. Such diffusion can alter the channel characteristics and compromise the passive device's performance. By confining the dopant diffusion, the spacers 334 can contribute to maintaining the desired device's characteristics and electrical behavior. In some embodiments, the spacers 334 can be formed over the sidewalls of the gate regions 312. The spacers 334 can be formed by deposition techniques. Alternatively, the spacers 334 can be formed by etching or selectively epitaxially growing the spacers 334 over the sidewalls of the gate regions 312. In various embodiments, the spacers 334 can include SiGe. In some embodiments, the STI 316 can be made of SiN, and the ILD 332 can be made of SiO2.

In some embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices.

In various embodiments, the gate regions 312 serve as control elements that regulate the flow of current through the semiconductor device. The gate regions 312 can be composed of a conductive material. The gate regions 312 can control the flow of electric current between the source and drain regions. In addition to acting as a switch, modulating the gate voltage can enable the gate regions 312 to control the current flowing through the channel region, resulting in amplified output signals.

In an embodiment, the gate regions 312 can enable the implementation of Boolean active operations, such as AND, OR, and NOT, by controlling the flow of current based on the input voltages. In some embodiments, the gate regions 312, along with other active device components, can facilitate the miniaturization and integration of electronic circuits. The ability to control the channel region's conductivity through the gate voltage allows for compact and highly efficient circuit designs.

The gate regions 312 can be formed between the set of N-type doped regions 310B and the set of P-type doped regions 310A, and between the S/D 340. A replacement metal gate (RMG) process can be used to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability. In order to fabricate the CA 324 and CA 342, portions of the ILD 332 and 350, the gate regions 312, the STI 316 is removed and filled with a suitable material to form the CA 324 and CA 342.

Generally, the source/drain regions, such as the S/D 340, are salient components that play relevant roles in the semiconductor device's operation. In various embodiments, the S/D 340 is region within the semiconductor material, e.g., the semiconductor device, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

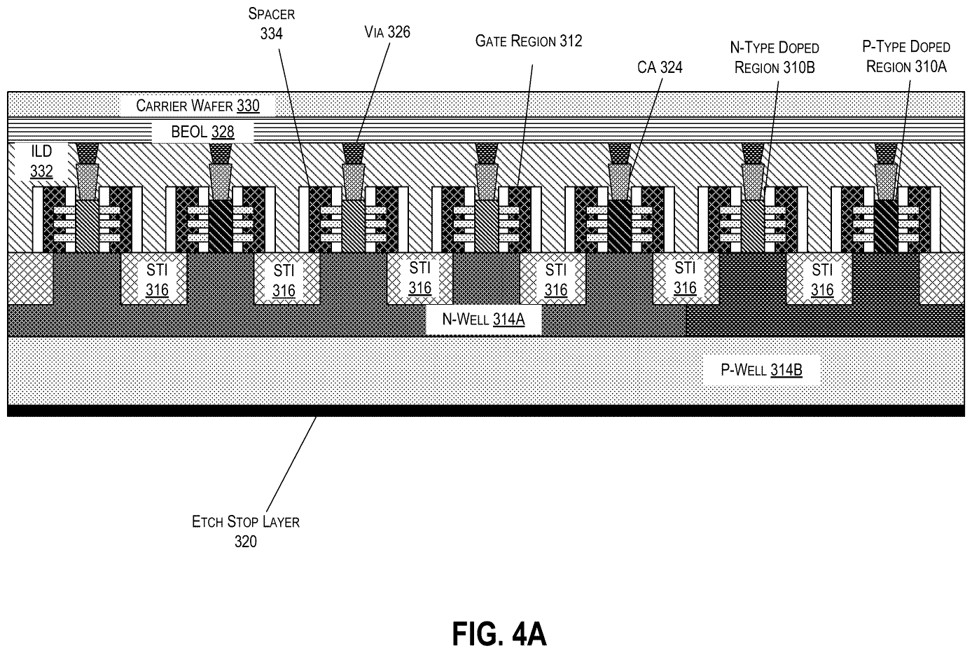

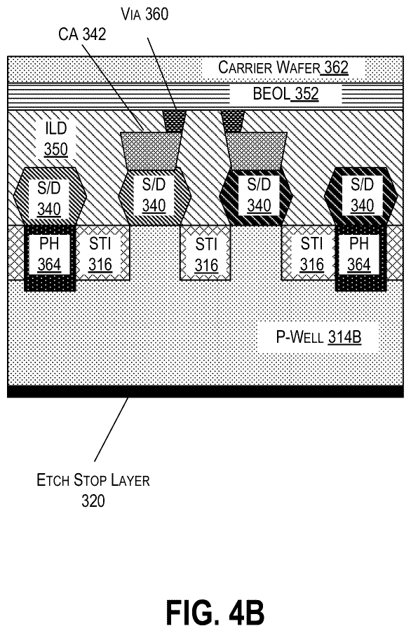

FIGS. 4A-4B illustrate a semiconductor device after the removal of the first substrate, in accordance with some embodiments. In some embodiments, the semiconductor device is flipped and the first substrate is removed. The first substrate removal stops at the etch stop layer 320.

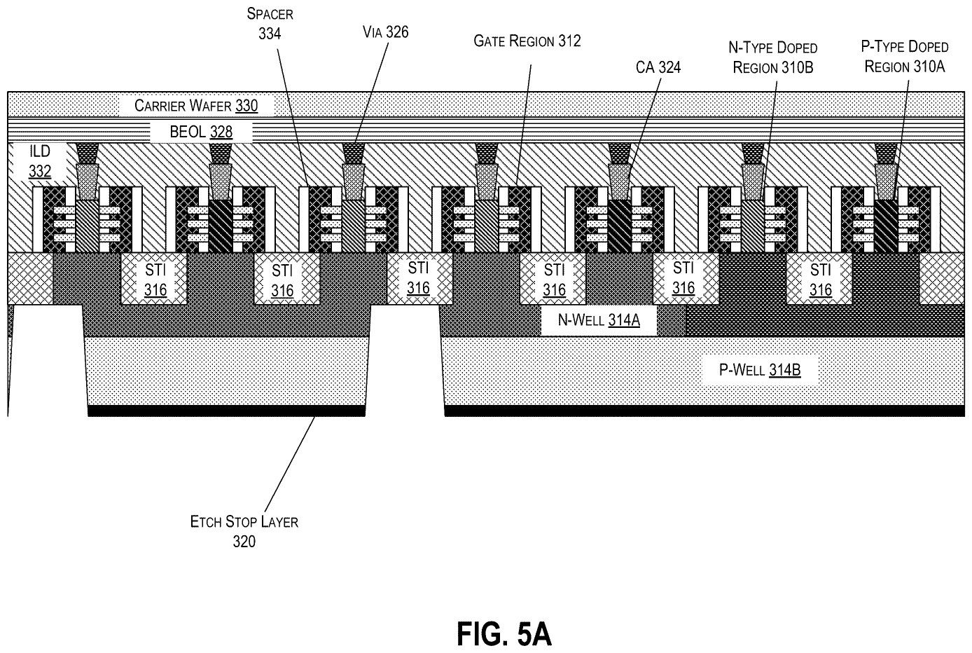

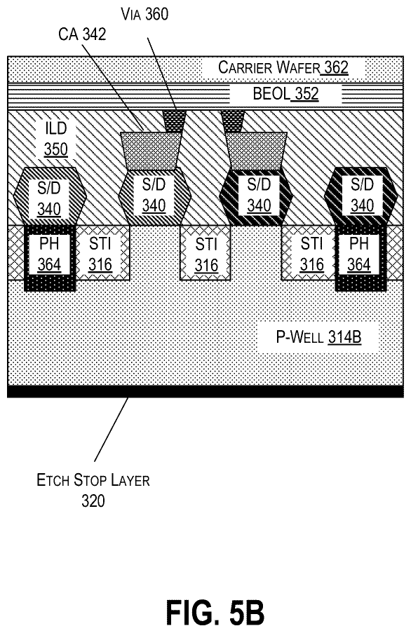

FIGS. 5A-5B illustrate a semiconductor device after the after the patterning of the substrate, in accordance with some embodiments. In some embodiments, the backside of the latch-up prone regio is patterned by removing portions of the etch stop layer and the Pe-well region.

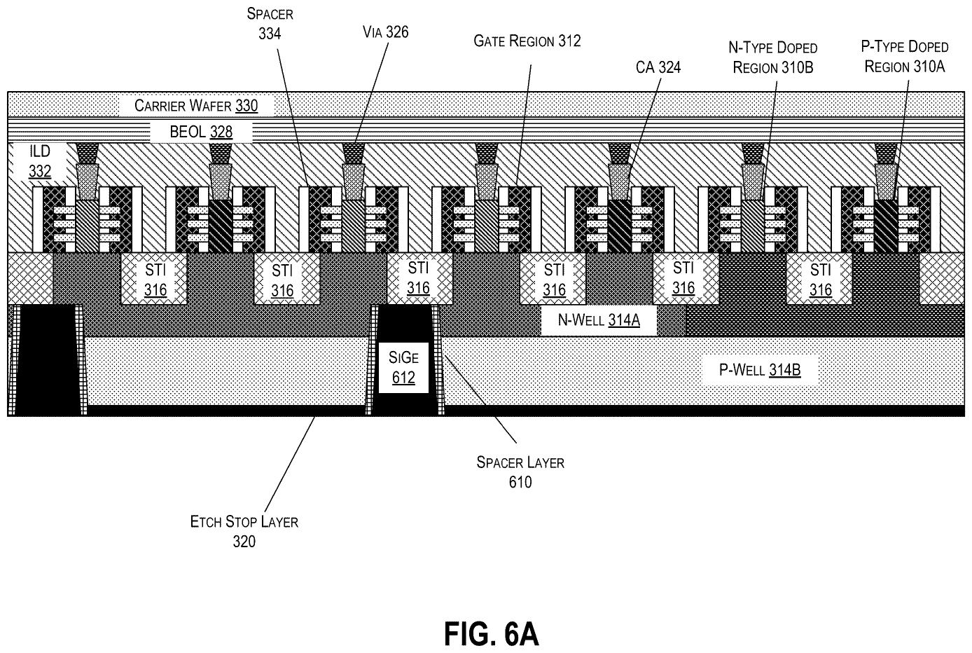

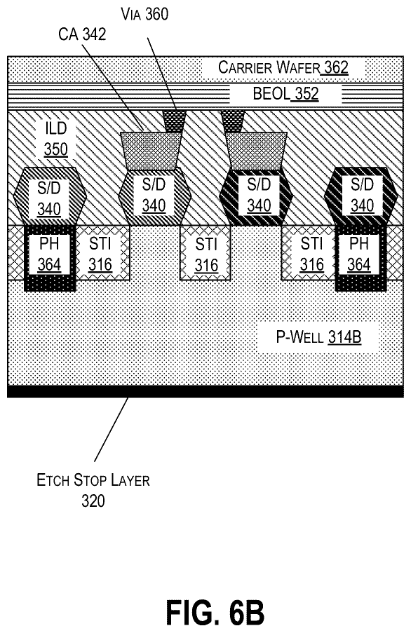

FIGS. 6A-6B illustrate a semiconductor device after the after the formation of the spacer layer, in accordance with some embodiments. In some embodiments, a spacer layer 610 is formed on the sidewalls of the patented portions of the semiconductor device, followed by a layer of SiGe 612 filling the remaining portions of the patterned portions of the semiconductor device.

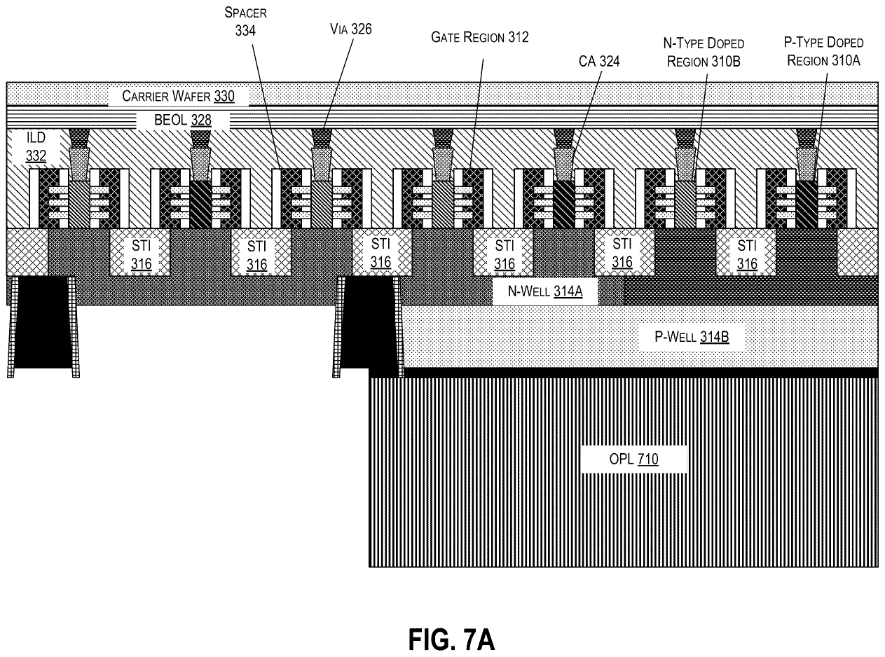

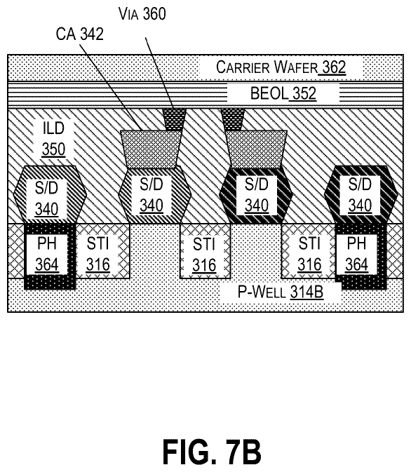

FIGS. 7A-7B illustrate a semiconductor device after the after the recession of the substrate, in accordance with some embodiments. In some embodiments, an organic planarization layer, OPL 710, is formed over the latch-up prone region. The OPL 710 can include a photo-sensitive organic polymer having a light-sensitive material that, when exposed to electromagnetic radiation, is chemically altered and thus configured to be removed using a developing solvent. For example, in some embodiments, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene. In some embodiments, the OPL 710 can include any organic polymer and a photoactive compound having a molecular structure that can attach to the molecular structure of the organic polymer. In some embodiments, the OPL 710 material is selected to be compatible with an overlying antireflective coating and/or an overlying photoresist. In some embodiments, the OPL 710 can be applied using spin coating technology, although other techniques are within the contemplated scope of the present disclosure. Subsequently, the exposed portions of the etch stop layer are removed. Uncovered portions of the first substrate, the etch stop layer and the second substrate are removed from the latch-up prone region and the active region.

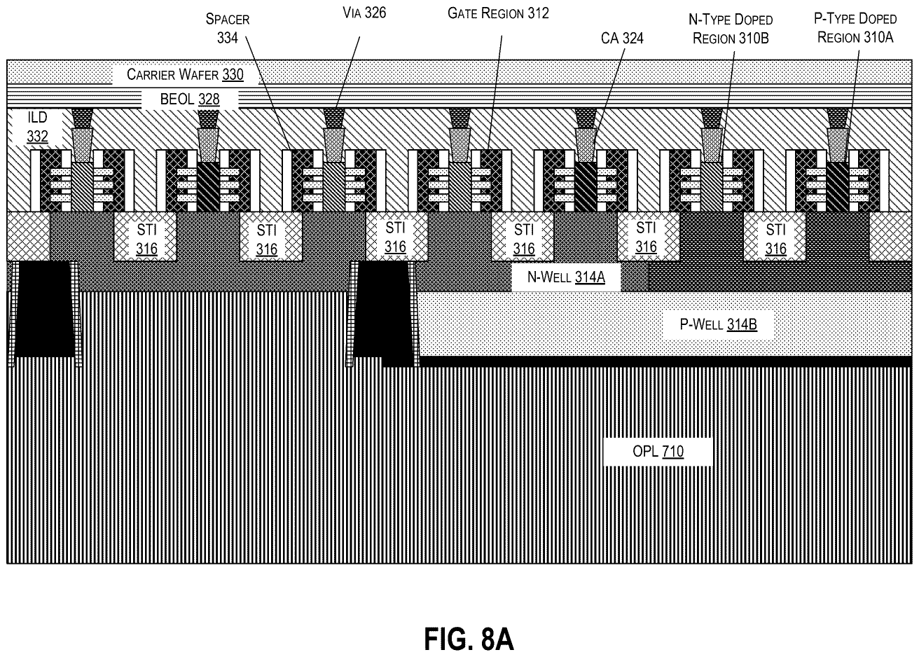

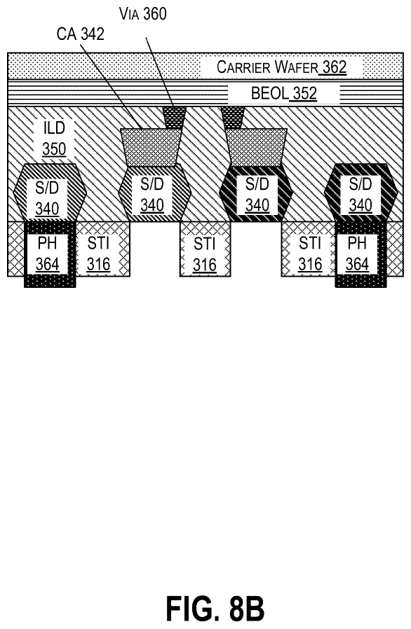

FIGS. 8A-8B illustrate a semiconductor device after the after the formation of a mask layer, in accordance with some embodiments. In some embodiments, an additional layer of OPL covers the entire latch-up prone region.

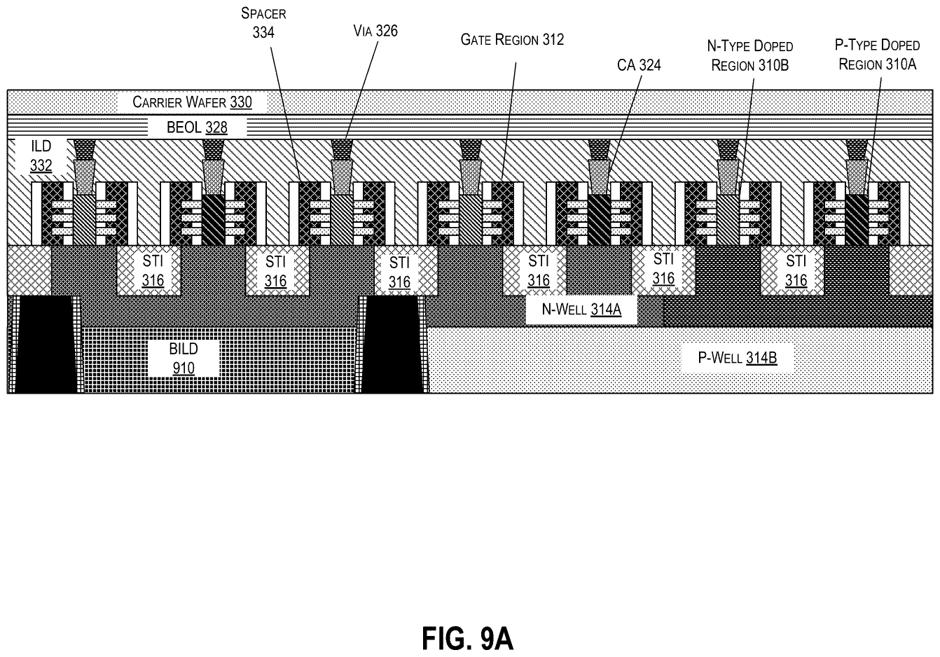

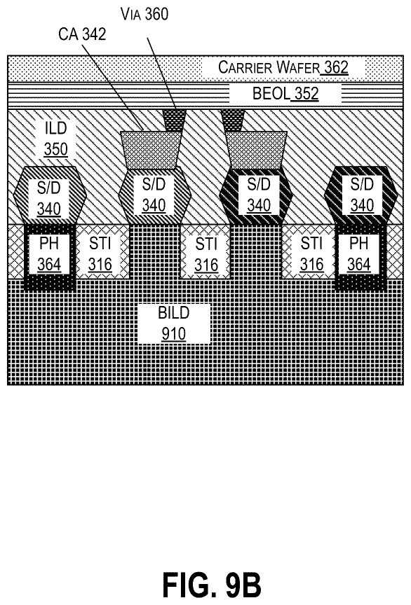

FIGS. 9A-9B illustrate a semiconductor device after the after the formation of the backside interlayer dielectric, in accordance with some embodiments. In some embodiments, the OPL is removed, and a BILD 910 is formed over the backside of the semiconductor device. In various embodiments, the BILD 910 can function as a protective layer, shielding the active regions of the semiconductor device from external contaminants, moisture, and mechanical stress. The BILD 910 can further help prevent physical damage, such as scratches or particle contamination, which could adversely affect semiconductor device performance. Additionally, the BILD 910 can function as a barrier against moisture ingress, which can cause corrosion and degradation of the semiconductor device's components. The BILD 910 can be made of SiO2. In an embodiment, a chemical-mechanical polishing (CMP) process is further processed after the formation of the BILD 910.

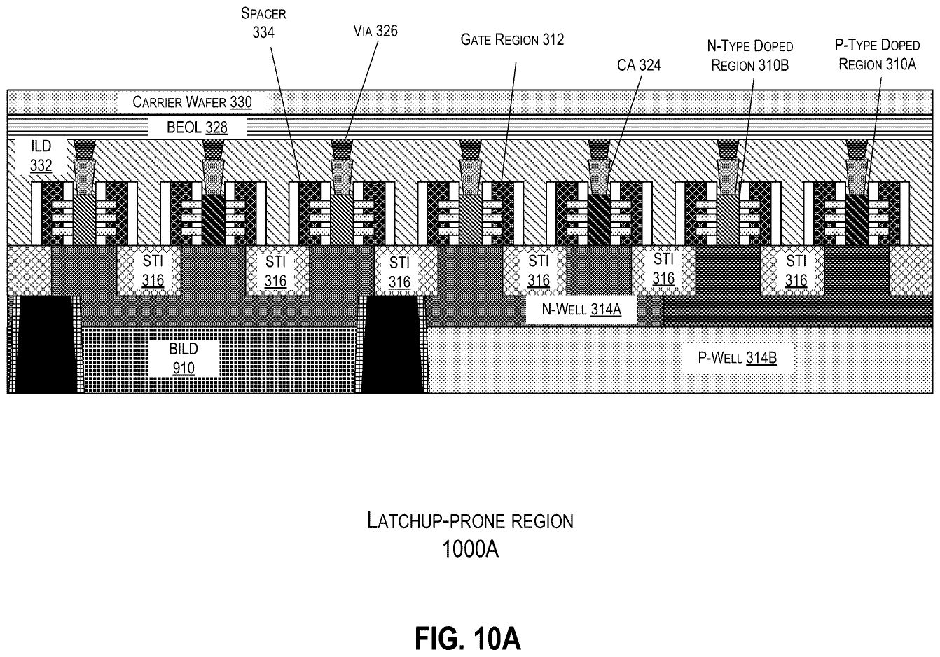

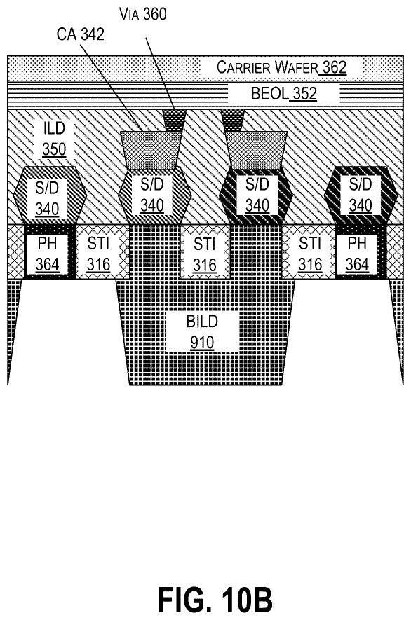

FIGS. 10A-10B illustrate a semiconductor device after the after the patterning of the backside interlayer dielectric, in accordance with some embodiments. In some embodiments, the BILD 910 is patterned in the active region to expose the PH 364.

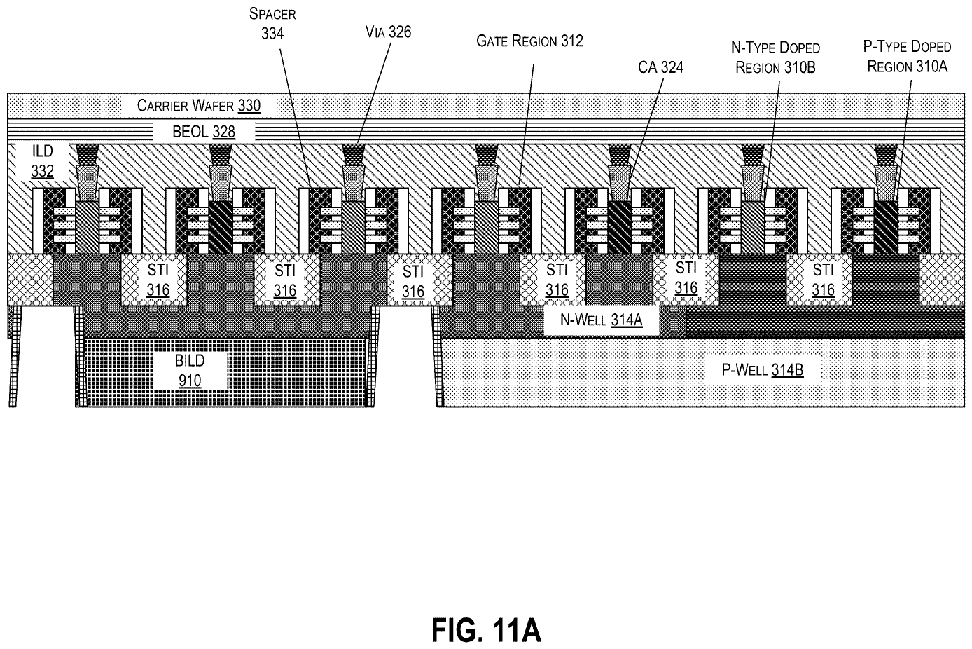

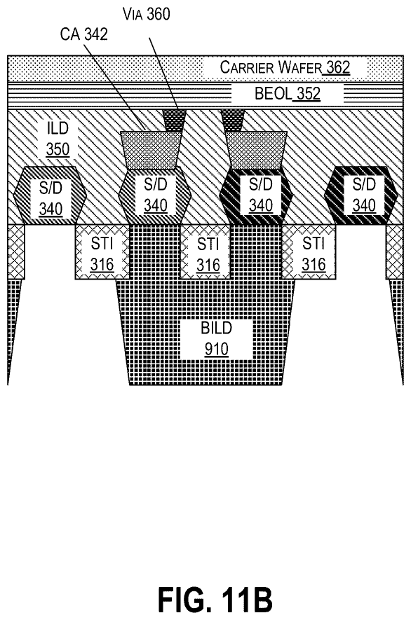

FIGS. 11A-11B illustrate a semiconductor device after the removal of the etch stop layer, in accordance with some embodiments. In some embodiments, the etch stop layer and the PH are removed.

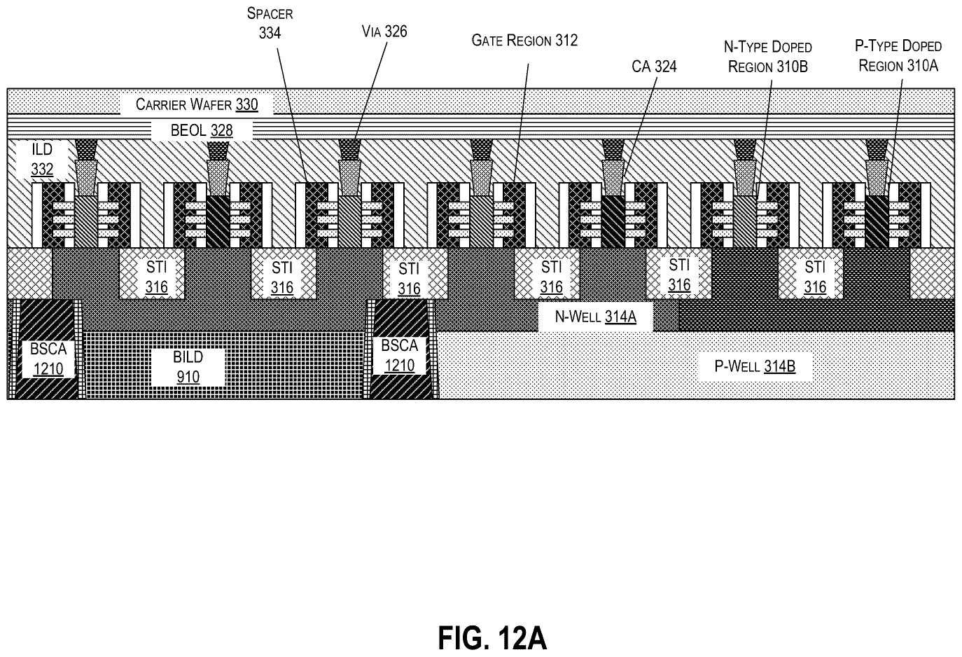

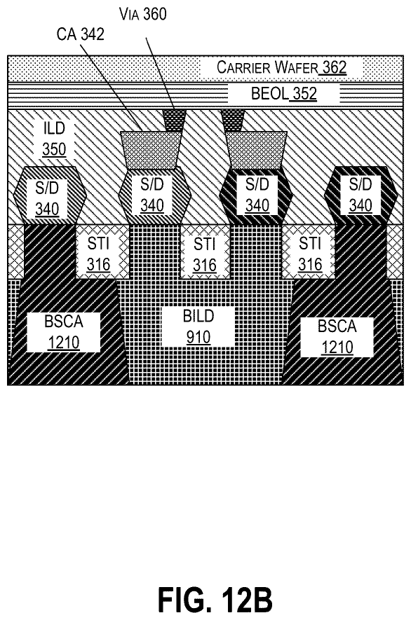

FIGS. 12A-12B illustrate a semiconductor device after the metallization of the backside contact, in accordance with some embodiments. In some embodiments, the backside contacts, BSCA 1210, are formed by filling the recessed areas with a suitable metal. The BSCA 1210 can be surrounded in by the BILD 910, the STI 316 and the spacer layer 610.

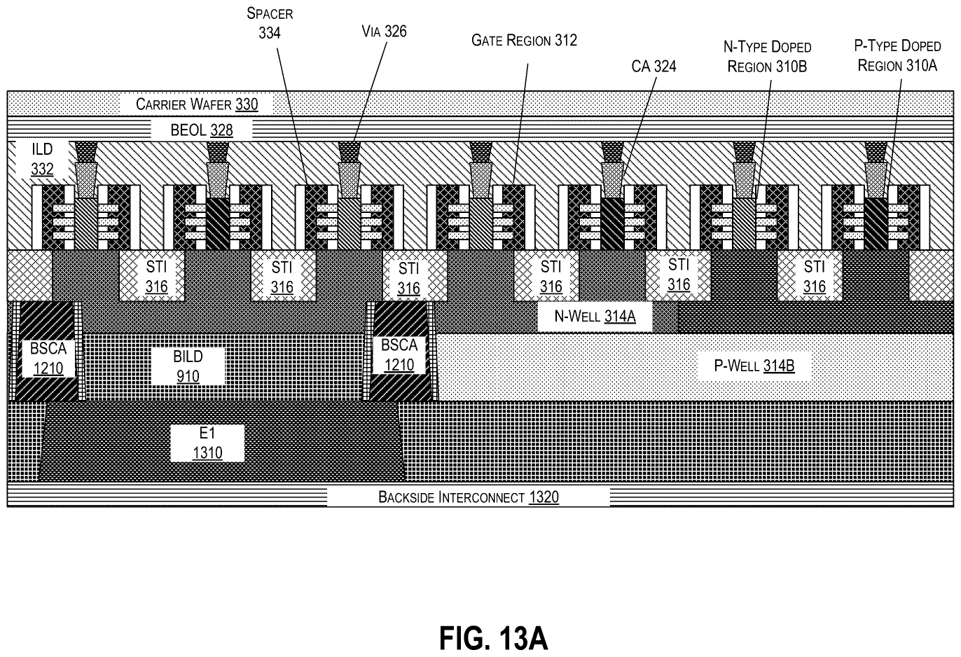

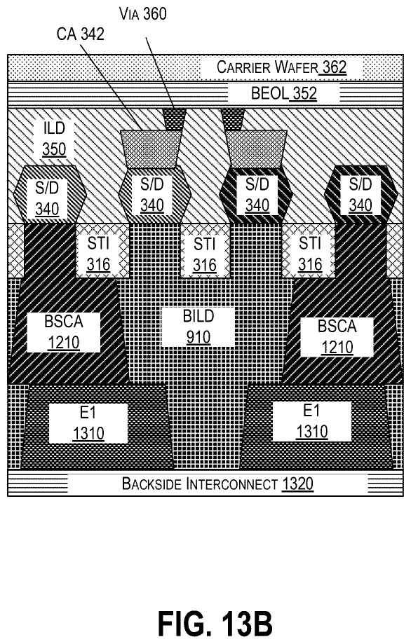

FIGS. 13A-13B illustrate a semiconductor device after the formation of the backside interconnects, in accordance with some embodiments. In some embodiments, a metal interconnect, E1 1310, is formed over the BILD 910. A backside interconnect 1320 is formed over the backside of the semiconductor device. The backside contact in the active region is not covered by a spacer layer to increase (e.g., maximize) the contact size.

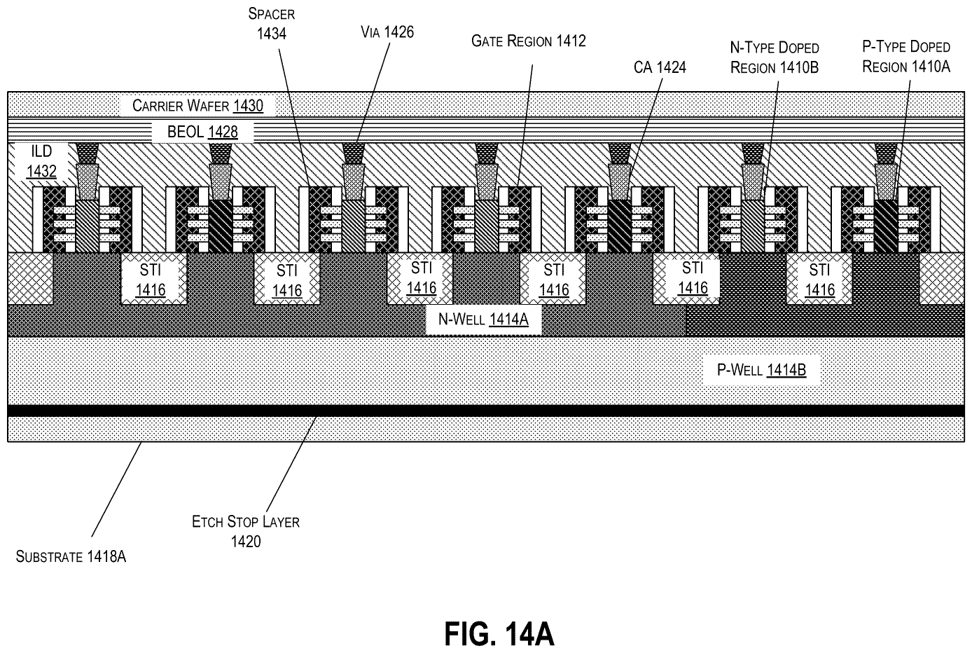

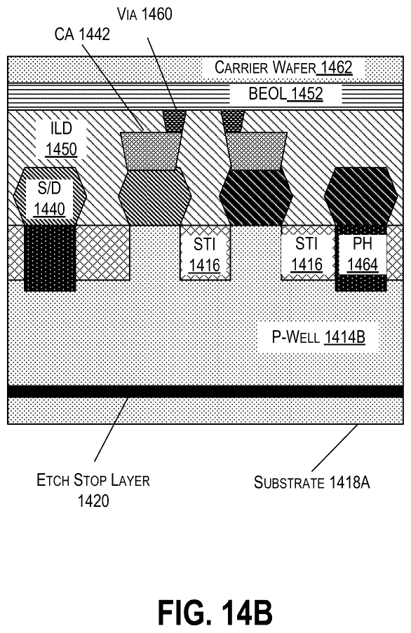

FIGS. 14-23 illustrate various acts in the manufacture of a semiconductor device, consistent with illustrative embodiments. Reference now is made to FIGS. 14A-14B, which are simplified cross-section views of a semiconductor device, after the front end of line (FEOL), middle of line (MOL), and BEOL, consistent with an illustrative embodiment. As noted above, the semiconductor device includes a latch-up prone region (which can be in parts of the passive device in the vicinity of the active device) and an active device. Figures denoted by A show the latch-up prone regions and figures denoted by B depict the active device region of the semiconductor device.

The latch-up prone region can a set of P-type doped regions 1410A, a set of N-type doped regions 1410B, gate regions 1412, an N-well region 1414A, a P-well region 1414B, a first shallow trench isolation, STI 1416, a substrate 1418A, an etch stop layer 1420, frontside contacts, CA 1424, a first set of vias 1426, a back end of line, BEOL 1428, a carrier wafer 1430, an interlayer dielectric, ILD 1432, and spacers 1434.

The active device, which can be a FET, includes source/drain regions, S/D 1440, frontside contacts, CA 1442, ILD 1450, BEOL 1452, a STI 1416, a second set of vias 1460, a carrier wafer 1462, PH 1464, the substrate 1418A, and the etch stop layer 1420. It should be noted that, in various embodiments, the latch-up prone region and the active device can share one or more of the BEOL, carrier wafer, first substrate, second substrate, etch stop layer, ILD and STI can be common.

In the illustrative example depicted in FIGS. 14A-14B, the semiconductor device is depicted as being on silicon as the substrate 1418A, while it will be understood that other types as the substrate 1418A may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate 1418A can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 1420 is formed over the substrate 1418A. The etch stop layer 1420 can be a thin layer of material incorporated into the structure of the semiconductor device to provide a selective barrier against etching processes, preventing further removal of underlying materials during fabrication. The etch stop layer 1420 can enable precise control over the etching depth and help define the desired device dimensions. The etch stop layer 1420 can further provide a stopping point for the etching process, ensuring that specific layers or regions are not etched beyond a certain point, leading to accurate patterning and control of critical features. The etch stop layer 1420 can create a distinct separation between different layers or components within the device structure, and prevent the undesired etching of underlying layers or materials, enabling the creation of complex, multi-layered structures with well-defined interfaces and boundaries. In some embodiments, the etch stop layer 1420 acts as a protective barrier for sensitive or delicate materials to shield such materials from aggressive etchants, preventing damage or degradation during subsequent fabrication steps.

In some embodiments, prior to forming the etch stop layer 1420, the substrate 1418A is prepared by cleaning and removing any impurities or oxide layers. The etch stop layer 1420 is deposited onto the substrate 1418A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 1420 can then be selectively etched, stopping at a predetermined depth, while protecting the underlying layers. After the etching process, the remaining photoresist can be removed through stripping techniques. While in some embodiments, SiGe is used to form the etch stop layer 1420, in some embodiments, silicon nitride (SiN), silicon oxide (SiO2), or silicon oxynitride (SiON) can be used as the etch stop layer 1420.

The spacers 1434 can be thin insulating layers or materials placed on the sidewalls of the gate regions 1412. The spacers 1434 can help control the effective channel length of the latch-up prone region. In an embodiment, the spacers 1434 can allow for control over the channel's conductive properties, including resistance and carrier mobility, which can contribute to improved performance of the semiconductor device. The spacers 1434 can be a low-k material.

In some embodiments, the spacers 1434 can act as insulating layers between the gate regions 1412 and the set of N-type doped regions 1410B and the set of P-type doped regions 1410A. That is, the spacers 1434 can help prevent current leakage or short circuits between the gate regions 1412 and the set of N-type doped regions 1410B and the set of P-type doped regions 1410A. Such isolation can help maintain the integrity of the passive device's electrical operation and prevent unintended current flow that could negatively impact the performance of the semiconductor device and reliability.

In further embodiments, the spacers 1434 can be utilized to modulate the overlapping capacitance between the gate regions 1412 and the set of N-type doped regions 1410B and the set of P-type doped regions 1410A. Overlapping capacitance can affect the passive device's electrical characteristics, such as threshold voltage and switching behavior. Thus, by adjusting the thickness and material properties of the spacers 1434 the overlapping capacitance can be optimized, which can allow for better control and modulation of the passive device's behavior. In several embodiments, the spacers 1434 can help mitigate the short-channel effects by physically separating the gate regions 1412 from the set of N-type doped regions 1410B and the set of P-type doped regions 1410A. To that end, the spacers 1434 can create a barrier that restricts the extension of the electric field into the channel region. This mitigation can improve the device's performance, reduce power consumption, and enhance overall device reliability.

In an embodiment, the spacers 1434 can serve as barriers that prevent the lateral diffusion of dopant atoms from the set of N-type doped regions 1410B and the set of P-type doped regions 1410A, and into the channel region during the doping process. Such diffusion can alter the channel characteristics and compromise the passive device's performance. By confining the dopant diffusion, the spacers 1434 can contribute to maintaining the desired device's characteristics and electrical behavior. In some embodiments, the spacers 1434 can be formed over the sidewalls of the gate regions 1412. The spacers 1434 can be formed by deposition techniques. Alternatively, the spacers 1434 can be formed by etching or selectively epitaxially growing the spacers 1434 over the sidewalls of the gate regions 1412. In various embodiments, the spacers 1434 can include SiGe. In some embodiments, the STI 1416 can be made of SiN, and the ILD 1432 can be made of SiO2.

In some embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices.

In various embodiments, the gate regions 1412 serve as control elements that regulate the flow of current through the semiconductor device. The gate regions 1412 can be composed of a conductive material. The gate regions 1412 can control the flow of electric current between the source and drain regions. In addition to acting as a switch, modulating the gate voltage can enable the gate regions 1412 to control the current flowing through the channel region, resulting in amplified output signals.

In an embodiment, the gate regions 1412 can enable the implementation of Boolean active operations, such as AND, OR, and NOT, by controlling the flow of current based on the input voltages. In some embodiments, the gate regions 1412, along with other active device components, can facilitate the miniaturization and integration of electronic circuits. The ability to control the channel region's conductivity through the gate voltage allows for compact and highly efficient circuit designs.

The gate regions 1412 can be formed between the set of N-type doped regions 1410B and the set of P-type doped regions 1410A, and between the S/D 1440. A replacement metal gate (RMG) process can be used to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability. In order to fabricate the CA 1424 and CA 1442, portions of the ILD 1432 and 1450, the gate regions 1412, the STI 1416 and STI 1416 are removed and filled with a suitable material to form the CA 1424 and CA 1442.

Generally, the source/drain regions, such as the S/D 1440, are salient components that play relevant roles in the semiconductor device's operation. In various embodiments, the S/D 1440 is region within the semiconductor material, e.g., the semiconductor device, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

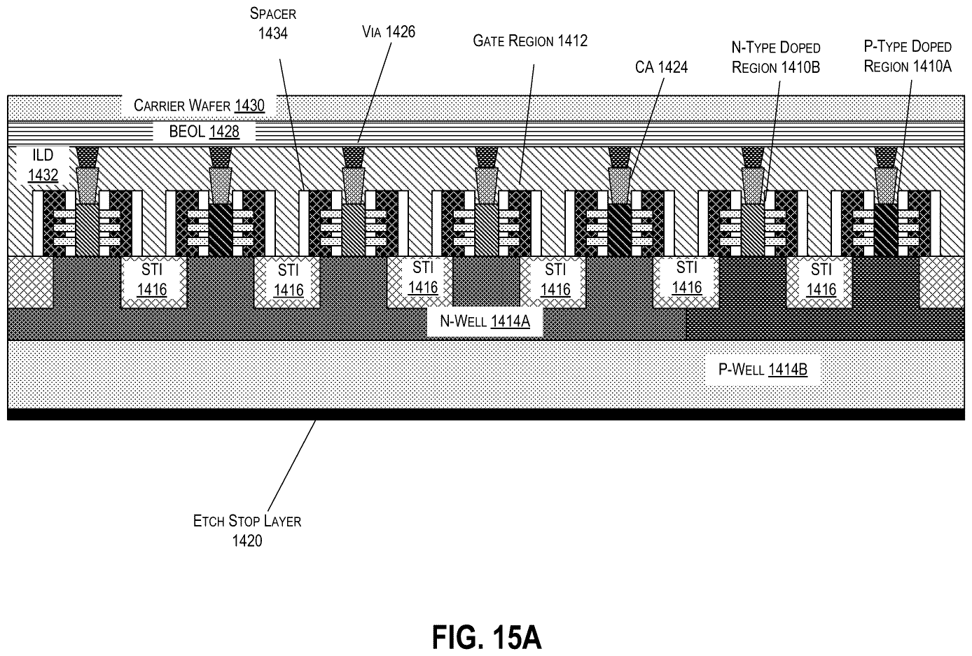

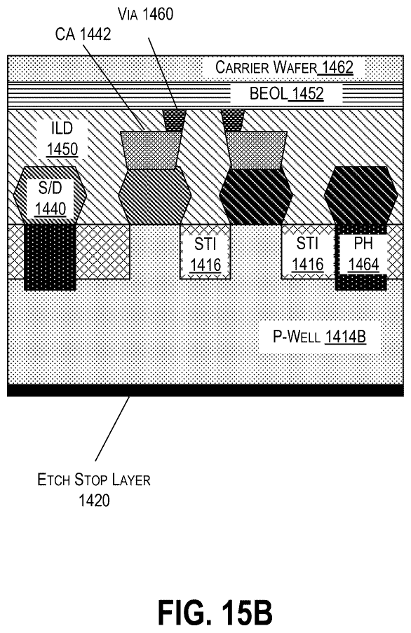

FIGS. 15A-15B illustrate a semiconductor device after the removal of the first substrate, in accordance with some embodiments. In some embodiments, the semiconductor device is flipped and the first substrate is removed. The first substrate removal stops at the etch stop layer 1420.

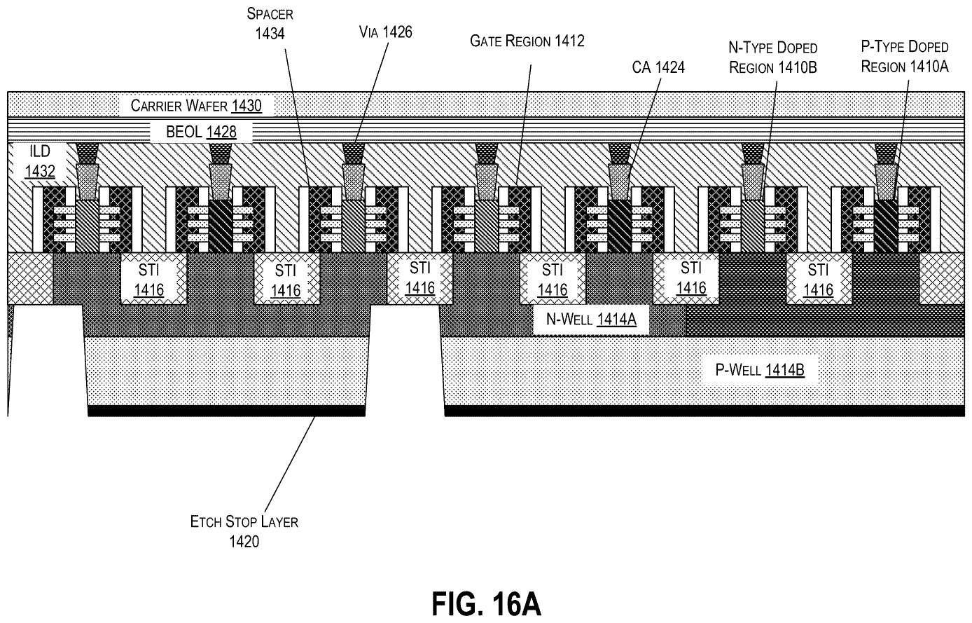

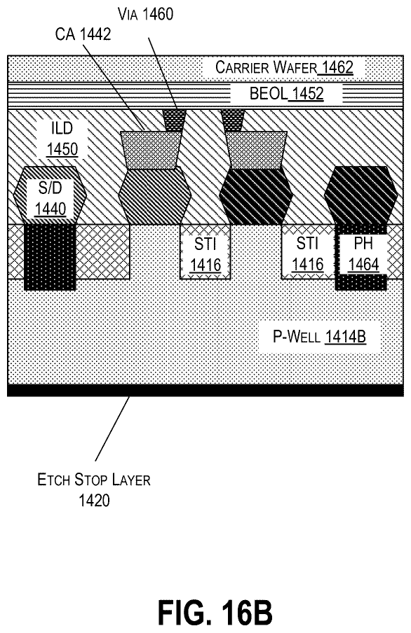

FIGS. 16A-16B illustrate a semiconductor device after the after the patterning of the substrate, in accordance with some embodiments. In some embodiments, the backside of the latch-up prone region is patterned by removing portions of the etch stop layer and the Pe-well region.

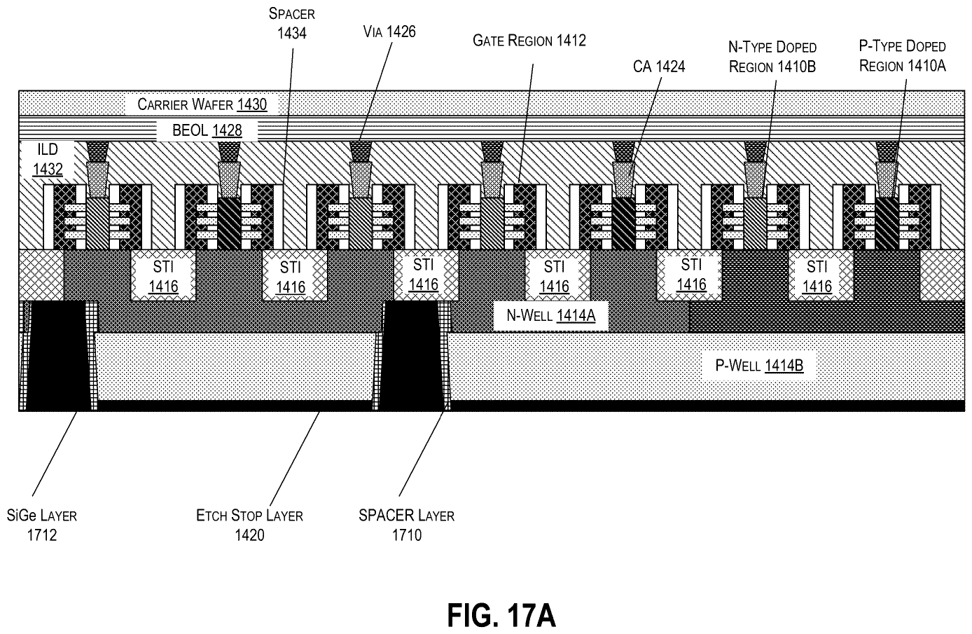

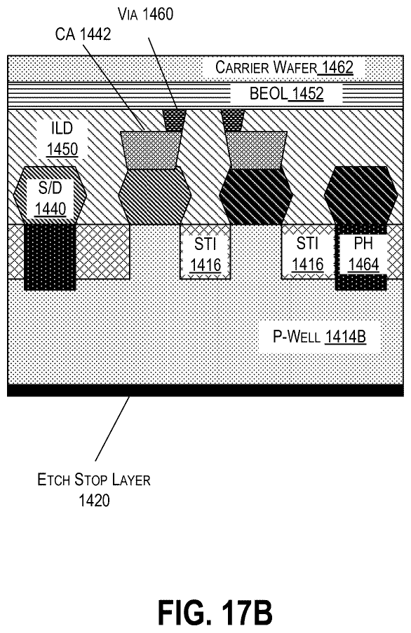

FIGS. 17A-17B illustrate a semiconductor device after the after the formation of the spacer layer, in accordance with some embodiments. In some embodiments, a spacer layer 1710 is formed on the sidewalls of the patented portions of the semiconductor device, followed by a layer of SiGe 1712 filling the remaining portions of the patterned portions of the semiconductor device.

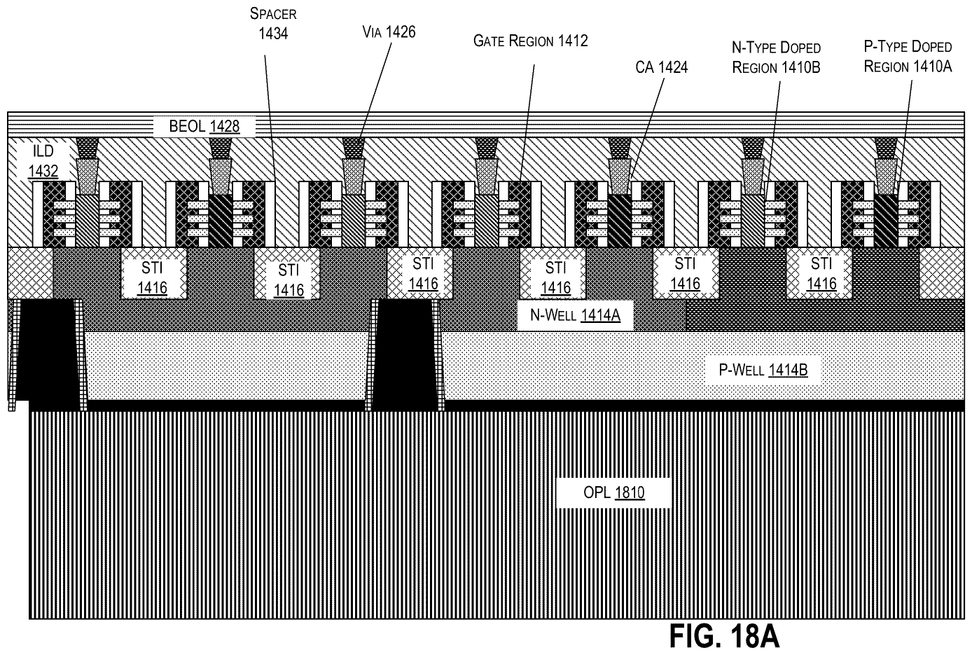

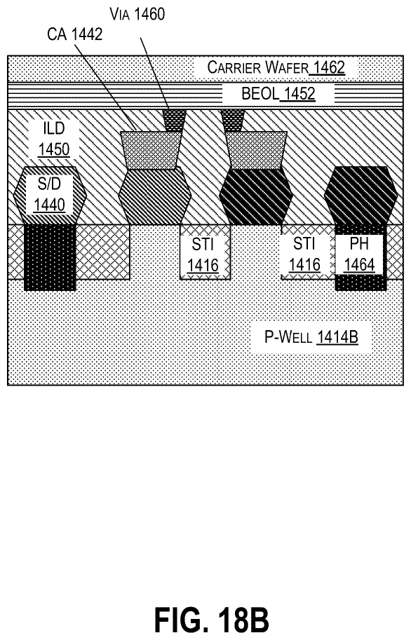

FIGS. 18A-18B illustrate a semiconductor device after the after the recession of the substrate, in accordance with some embodiments. In some embodiments, an organic planarization layer, OPL 1810, is formed over the latch-up prone region. The OPL 1810 can include a photo-sensitive organic polymer having a light-sensitive material that, when exposed to electromagnetic radiation, is chemically altered and thus configured to be removed using a developing solvent. For example, in some embodiments, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene. In some embodiments, the OPL 1810 can include any organic polymer and a photoactive compound having a molecular structure that can attach to the molecular structure of the organic polymer. In some embodiments, the OPL 1810 material is selected to be compatible with an overlying antireflective coating and/or an overlying photoresist. In some embodiments, the OPL 1810 can be applied using spin coating technology, although other techniques are within the contemplated scope of the present disclosure. Subsequently, the exposed portions of the etch stop layer are removed. Uncovered portions of the first substrate and the etch stop layer are removed from the active region.

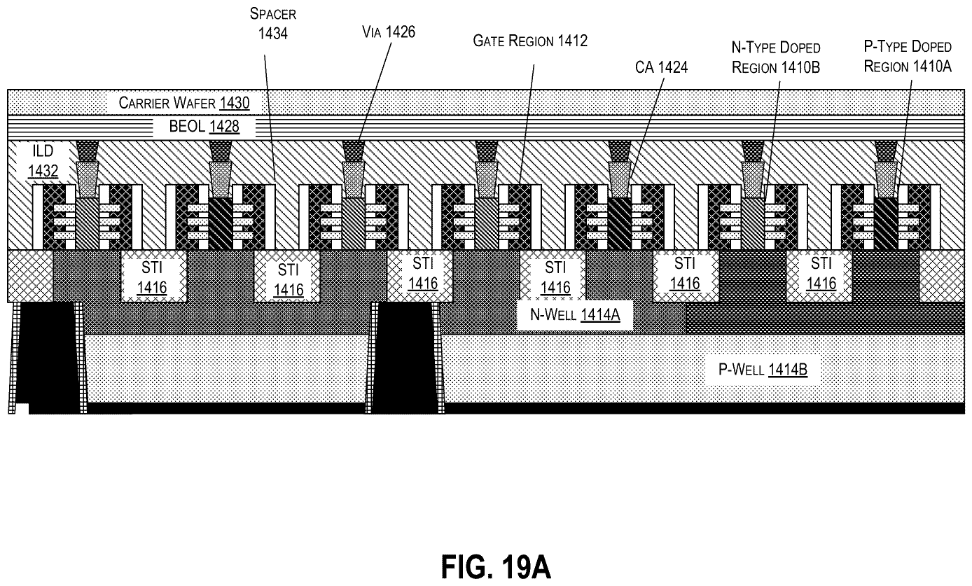

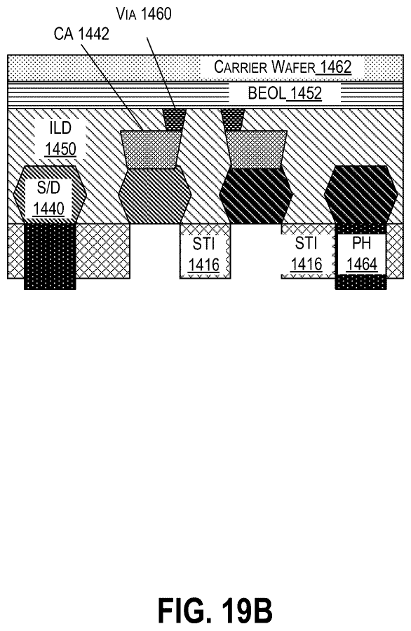

FIGS. 19A-19B illustrate a semiconductor device after the after the removal of the substrate, in accordance with some embodiments. In some embodiments, the OPL and the second substrate are removed.

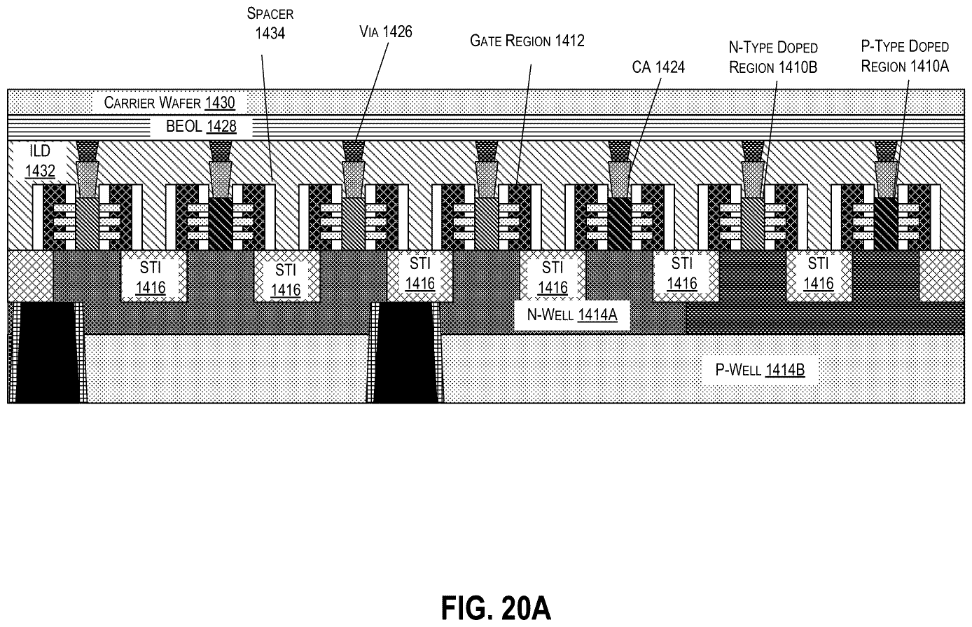

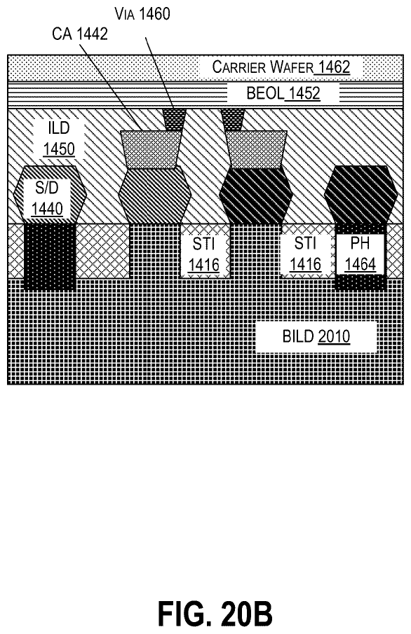

FIGS. 20A-20B illustrate a semiconductor device after the after the formation of the backside interlayer dielectric, in accordance with some embodiments. In some embodiments, a BILD 2010 is formed over the backside of the semiconductor device in the active region. In various embodiments, the BILD 2010 can function as a protective layer, shielding the active regions of the semiconductor device from external contaminants, moisture, and mechanical stress. The BILD 2010 can further help prevent physical damage, such as scratches or particle contamination, which could adversely affect semiconductor device performance. Additionally, the BILD 2010 can function as a barrier against moisture ingress, which can cause corrosion and degradation of the semiconductor device's components. The BILD 2010 can be made of SiO2. In an embodiment, a chemical-mechanical polishing (CMP) process is further processed after the formation of the BILD 2010.

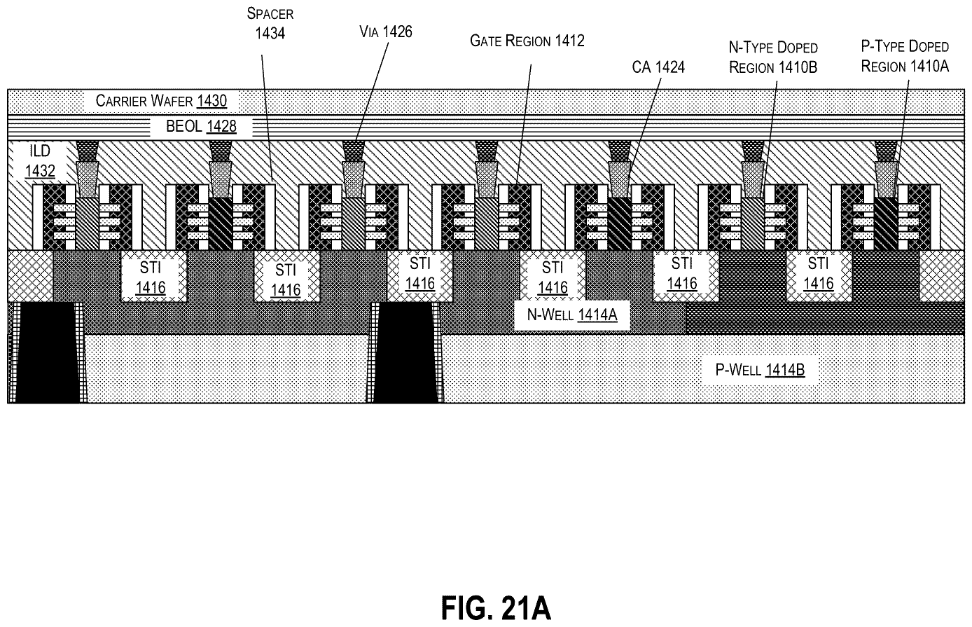

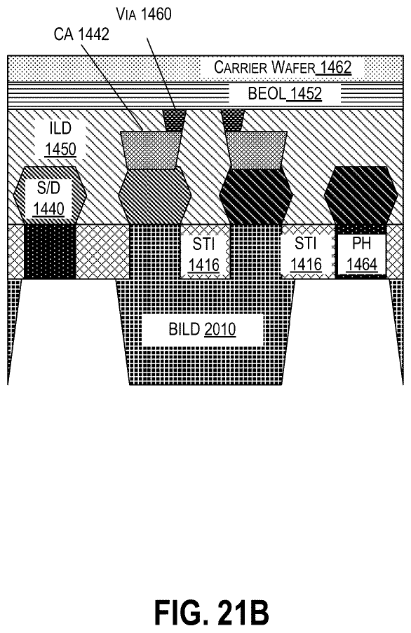

FIGS. 21A-21B illustrate a semiconductor device after the after the patterning of the backside interlayer dielectric, in accordance with some embodiments. In some embodiments, the BILD 2010 is patterned in the active region to expose the PH 1464.

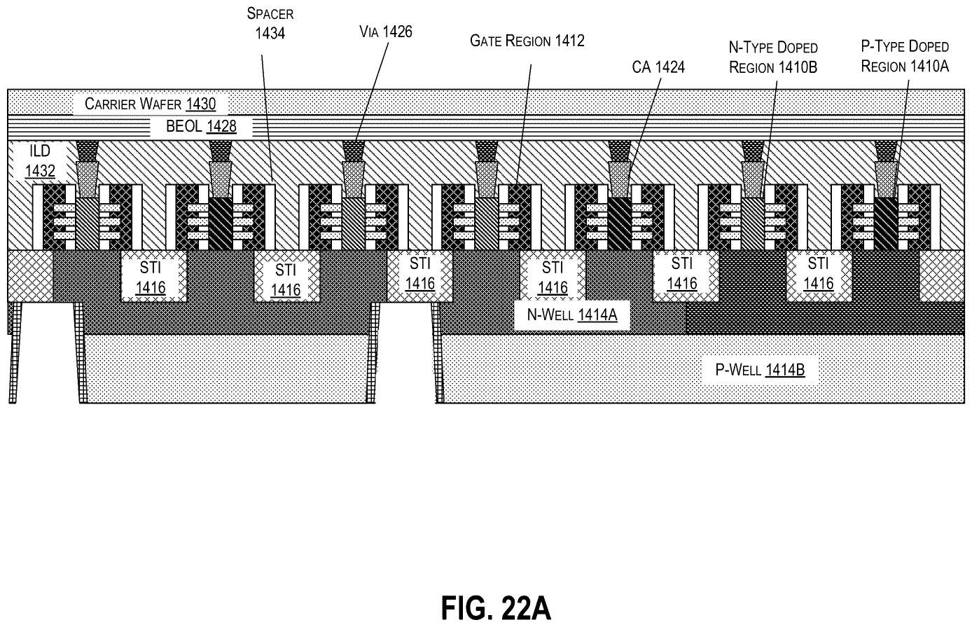

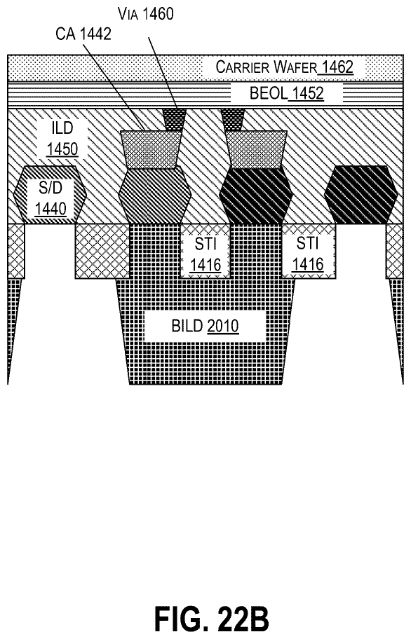

FIGS. 22A-22B illustrate a semiconductor device after the removal of the etch stop layer, in accordance with some embodiments. In some embodiments, the etch stop layer and the PH are removed.

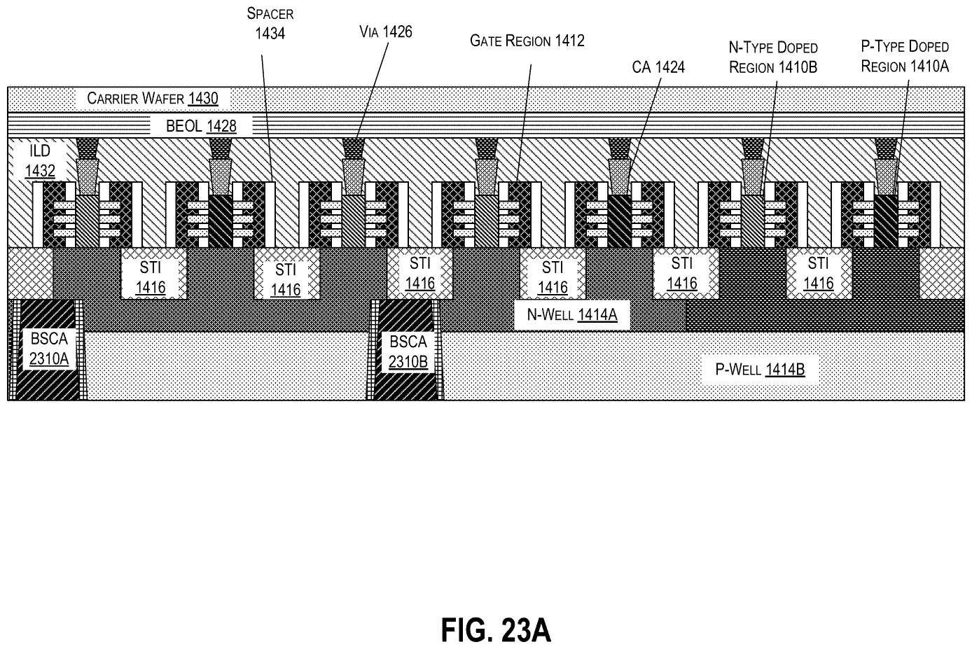

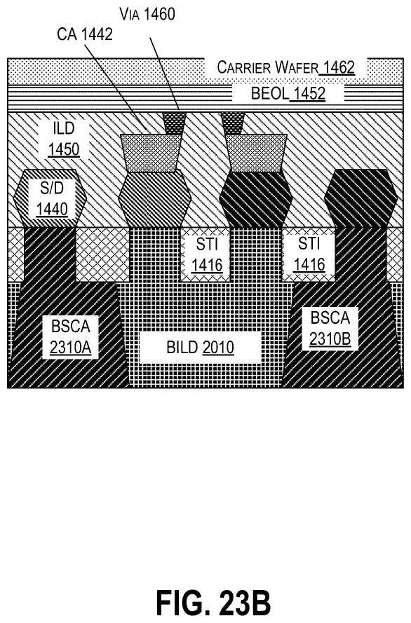

FIGS. 23A-23B illustrate a semiconductor device after the metallization of the backside contact, in accordance with some embodiments. In some embodiments, the backside contacts, BSCA 2310A and BSCA 2310B, are formed by filling the recessed areas with a suitable metal. The BSCA 2310A and BSCA 2310B can be surrounded in by the BILD 2010, the STI 1416, the P-well region, and the spacer layer 1710.

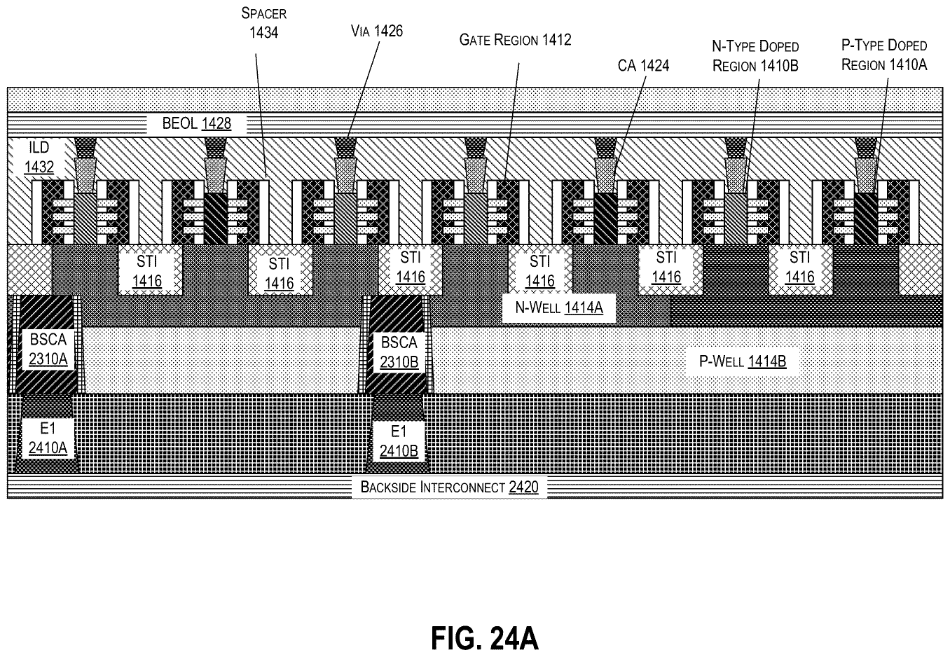

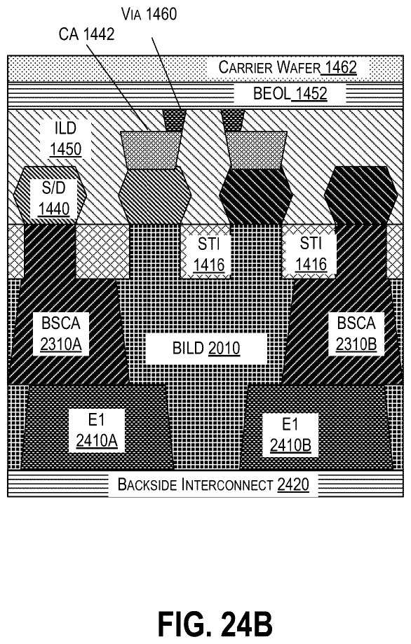

FIGS. 24A-24B illustrate a semiconductor device after the formation of the backside interconnects, in accordance with some embodiments. In some embodiments, a first metal interconnect, E1 2410A, is formed below the BSCA 2310A and a second metal interconnect, E1 2410B, is formed below the BSCA 2310B. A backside interconnect 2420 is formed over the backside of the semiconductor device. The backside contact in the active region are not covered by a spacer layer to increase (e.g., maximize) the contact size.

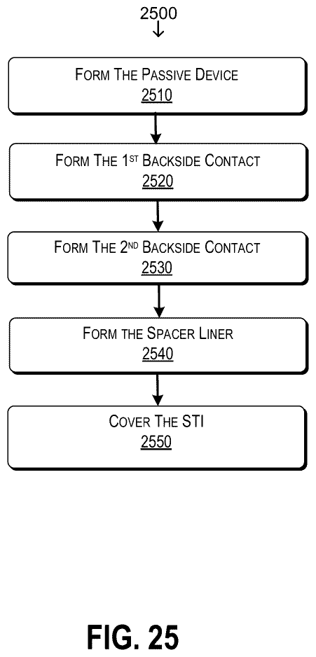

FIG. 25 illustrates a block diagram of a method 2500 for forming the semiconductor device, in accordance with some embodiments. As shown by block 2510, the passive device is formed.

As shown by block 2520, a first backside contact is formed.

As shown by block 2530, a second backside contact is formed.

As shown by block 2540, the spacer liner is formed. The spacer liner can cover sidewalls of the first backside contact and the second backside contact.

As shown by block 2550, the shallow trench isolation (STI) is formed. The STI can cover the first backside contact and the second backside contact and partially cover a top surface of the first backside contact and the second backside contact. The spacer liner can prevent carrier transportation from the passive device.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a passive device, comprising:
a first backside contact on a first side of the passive device;
a second backside contact on a second side of the passive device;
a spacer liner over sidewalls of the first backside contact and the second backside contact; and
a shallow trench isolation (STI) above the first backside contact and the second backside contact and partially covering a top surface of the first backside contact and the second backside contact, wherein the spacer liner is configured to prevent carrier transportation from the passive device.

2. The semiconductor device of claim 1, wherein the passive device further comprises:
a bottom dielectric layer (BILD) between the first backside contact and the second backside contact;
a well region between the STI and the BILD; and
a metal interconnect connecting the passive device to a backside power delivery network (BSPDN).

3. The semiconductor device of claim 1, further comprising:
a set of P-type doped regions and a set of N-type doped regions over the STI and a doped region; and
a first set of gate regions.

4. The semiconductor device of claim 1, wherein the spacer liner is made of a high-k dielectric material.

5. The semiconductor device of claim 1, wherein the passive device is electrically connected to a back end of line (BEOL) through a via and a first contact.

6. The semiconductor device of claim 1, further comprising:
an active device, comprising:
source/drain regions;
a second set of gate regions; and
a second contact.

7. The semiconductor device of claim 6, wherein the active device is electrically connected to a back end of line (BEOL) through a second via.

8. The semiconductor device of claim 6, wherein the active device further comprises alternative layers extended horizontally between two adjacent source/drain regions.

9. The semiconductor device of claim 8, wherein the alternative layers include silicon.

10. A method of fabricating a semiconductor device, the method comprising:
forming a passive device comprising:
forming a first backside contact;
forming a second backside contact;
forming a spacer liner over sidewalls of the first backside contact and the second backside contact; and
forming a shallow trench isolation (STI) above the first backside contact and the second backside contact and partially covering a top surface of the first backside contact and the second backside contact, wherein the spacer liner is configured to prevent carrier transportation from the passive device.

11. The method of claim 10, further comprising:
forming a bottom dielectric layer (BILD) adjacent to the first backside contact and the second backside contact;
forming a well region between the STI and the BILD; and
forming a metal interconnect connecting the passive device to a backside power delivery network (BSPDN).

12. The method of claim 11, further comprising:
forming a set of P-type doped regions and a set of N-type doped regions over the STI and a doped region; and
forming a first set of gate regions.

13. The method of claim 10, further comprising establishing an electrical connection between the passive device and a back end of line (BEOL) through a first via and a first contact.

14. The method of claim 10, further comprising:
forming an active device, comprising:
forming source/drain regions;
forming a second set of gate regions between the source/drain regions; and
forming a second contact over each of the source/drain regions.

15. The method of claim 14, further comprising forming alternative layers extended horizontally between two adjacent source/drain regions.

16. The method of claim 15, further comprising establishing an electrical connection between the active device and a back end of line (BEOL) through a second via.

17. A semiconductor device, comprising:
a passive device, comprising:
a first backside contact on a first side of the passive device;
a second backside contact on a second side of the passive device;
a first interconnect connecting the first backside contact to a backside power delivery network (BSPDN) on a backside of the passive device;
a second interconnect connecting the second backside contact to the BSPDN; and
a spacer liner over sidewalls of the first backside contact and the second backside contact, wherein the spacer liner is configured to prevent carrier transportation from the passive device.

18. The semiconductor device of claim 17, further comprising:
a shallow trench isolation (STI) above the first backside contact and the second backside contact and covering a top surface of the first backside contact and the second backside contact.

19. The semiconductor device of claim 18, further comprising:
a bottom dielectric layer (BILD) between the first interconnect and the second interconnect;
a first well region between the first backside contact and the second backside contact; and
a second well region between the STI and the first well region.

20. The semiconductor device of claim 17, further comprising:
an active device, comprising:
source/drain regions;
gate regions; and
a contact.
